(19) United States
(12) Patent Application Publication
(10) Pub. No.: US 2024/0194264 A1
(43) Pub. Date: Jun. 13, 2024

(54) MEMORY CELLS AND MEMORY ARRAY STRUCTURES AND METHODS OF THEIR FABRICATION

(71) Applicant: MICRON TECHNOLOGY, INC., Boise, ID (US)

(72) Inventors: Dmitry Mikulik, Meridian, ID (US); Leo Lukose, Leuven (BE); Ramanathan Gandhi, Singapore (SG)

(73) Assignee: MICRON TECHNOLOGY, INC., Boise, ID (US)

(21) Appl. No.: 18/515,906

(22) Filed: Nov. 21, 2023

Related U.S. Application Data
(60) Provisional application No. 63/432,113, filed on Dec. 13, 2022.

(51) Int. Cl. G11C 16/04; G11C 5/06; H10B 41/27; H10B 41/35; H10B 43/27; H10B 43/35

(52) U.S. Cl. CPC G11C 16/0483; G11C 5/063; H10B 41/27; H10B 41/35; H10B 43/27; H10B 43/35

(57) ABSTRACT

Memory cells, and memories and memory array structures containing such memory cells, might include a control gate, a channel, a gate dielectric between the channel and the control gate, a charge-storage node between the gate dielectric and the control gate, a charge-blocking material between the charge-storage node and the control gate, a laminated dielectric between the charge-blocking material and the control gate, and a high-K dielectric between the laminated dielectric and the control gate, wherein the laminated dielectric comprises an instance of a first dielectric material between the charge-blocking material and the high-K dielectric and an instance of a second dielectric material between the instance of the first dielectric material and the high-K dielectric, and wherein the instance of the first dielectric material has a higher oxygen areal density than an oxygen areal density of the instance of the second dielectric material.

### RELATED APPLICATION

This application claims the benefit of U.S. Provisional Application No. 63/432,113, filed on Dec. 13, 2022, hereby incorporated herein in its entirety by reference.

### TECHNICAL FIELD

The present disclosure relates generally to integrated circuits, and, in particular, in one or more embodiments, the present disclosure relates to memory cells and memory array structures and methods of their fabrication, as well as apparatus containing such memory array structures.

### BACKGROUND

Memories (e.g., memory devices) are typically provided as internal, semiconductor, integrated circuit devices in computers or other electronic devices. There are many different types of memory including random-access memory (RAM), read only memory (ROM), dynamic random access memory (DRAM), synchronous dynamic random access memory (SDRAM), and flash memory.

Flash memory has developed into a popular source of non-volatile memory for a wide range of electronic applications. Flash memory typically use a one-transistor memory cell that allows for high memory densities, high reliability, and low power consumption. Changes in threshold voltage (Vt) of the memory cells, through programming (which is often referred to as writing) of charge storage structures (e.g., floating gates or charge traps) or other physical phenomena (e.g., phase change or polarization), determine the data state (e.g., data value) of each memory cell. Common uses for flash memory and other non-volatile memory include personal computers, personal digital assistants (PDAs), digital cameras, digital media players, digital recorders, games, appliances, vehicles, wireless devices, mobile telephones, and removable memory modules, and the uses for non-volatile memory continue to expand.

A NAND flash memory is a common type of flash memory device, so called for the logical form in which the basic memory cell configuration is arranged. Typically, the array of memory cells for NAND flash memory is arranged such that the control gate of each memory cell of a row of the array is connected together to form an access line, such as a word line. Columns of the array include strings (often termed NAND strings) of memory cells connected together in series between a pair of select gates, e.g., a source select transistor and a drain select transistor. Each source select transistor might be connected to a source, while each drain select transistor might be connected to a data line, such as column bit line. Variations using more than one select gate between a string of memory cells and the source, and/or between the string of memory cells and the data line, are known.

Memory cells are typically erased before they are programmed to a desired data state. For example, memory cells of a particular block of memory cells may first be erased and then selectively programmed. For a NAND array, a block of memory cells is typically erased by grounding all of the access lines (e.g., word lines) in the block and applying an erase voltage to the channel regions of the memory cells (e.g., through data lines and source connections) in order to remove charges that might be stored to charge-storage structures (e.g., floating gates or charge traps) of the block of memory cells. Typical erase voltages might be on the order of 20V or more before completion of an erase operation. As memory cells experience higher numbers of program-erase cycles, erasing of memory cells typically becomes more difficult as electrons become trapped in the memory cell structure.

### BRIEF DESCRIPTION OF THE DRAWINGS

FIG. 1 is a simplified block diagram of a memory in communication with a processor as part of an electronic system, according to an embodiment.

FIGS. 2A-2B are schematics of portions of an array of memory cells as could be used in a memory of the type described with reference to FIG. 1.

FIG. 3A depicts various components of a memory cell of the related art.

FIG. 3B depicts an energy band diagram for the structure of FIG. 3A.

FIG. 4A depicts various components of a memory cell in accordance with an embodiment.

FIG. 4B depicts an energy band diagram for the structure of FIG. 4A.

FIG. 5 depicts a graph of normalized oxygen areal density as a function of cation radius of a number of dielectric materials that could be used with various embodiments.

FIG. 6A depicts a cross-sectional view of a memory array structure in accordance with embodiments.

FIG. 6B depicts an exploded portion of the memory array structure of FIG. 6A.

FIG. 7A depicts a cross-sectional view of a memory array structure in accordance with other embodiments.

FIG. 7B depicts an exploded portion of the memory array structure of FIG. 7A.

FIGS. 8A-8B depicts various components of a memory cell in accordance with embodiments.

FIG. 9A depicts different interfaces of an embodiment for use in discussing differences in concentration of dielectric materials across interfaces.

FIGS. 9B-9C depict graphs of concentration of different dielectric materials across different interfaces for some embodiments.

FIG. 10 depicts different interfaces of an embodiment for use in discussing differences in surface roughness of interfaces.

FIGS. 11A-11N depict a memory array structure during various stages of fabrication in accordance with an embodiment.

FIGS. 12A-12F depict a memory array structure during various stages of fabrication in accordance with an embodiment.

### DETAILED DESCRIPTION

In the following detailed description, reference is made to the accompanying drawings that form a part hereof, and in which is shown, by way of illustration, specific embodiments. In the drawings, like reference numerals describe substantially similar components throughout the several views. Other embodiments might be utilized and structural, logical and electrical changes might be made without departing from the scope of the present disclosure. The following detailed description is, therefore, not to be taken in a limiting sense.

The term “semiconductor” used herein can refer to, for example, a layer of material, a wafer, or a substrate, and includes any base semiconductor structure. “Semiconductor” is to be understood as including silicon-on-sapphire (SOS) technology, silicon-on-insulator (SOI) technology, thin film transistor (TFT) technology, doped and undoped semiconductors, epitaxial layers of a silicon supported by a base semiconductor structure, as well as other semiconductor structures well known to one skilled in the art. Furthermore, when reference is made to a semiconductor in the following description, previous process steps might have been utilized to form regions/junctions in the base semiconductor structure, and the term semiconductor can include the underlying layers containing such regions/junctions.

The term “conductive” as used herein, as well as its various related forms, e.g., conduct, conductively, conducting, conduction, conductivity, etc., refers to electrically conductive unless otherwise apparent from the context. Similarly, the term “connecting” as used herein, as well as its various related forms, e.g., connect, connected, connection, etc., refers to electrically connecting by an electrically conductive path unless otherwise apparent from the context.

It is recognized herein that even where values might be intended to be equal, variabilities and accuracies of industrial processing and operation might lead to differences from their intended values. These variabilities and accuracies will generally be dependent upon the technology utilized in fabrication and operation of the integrated circuit device. As such, if values are intended to be equal, those values are deemed to be equal regardless of their resulting values.

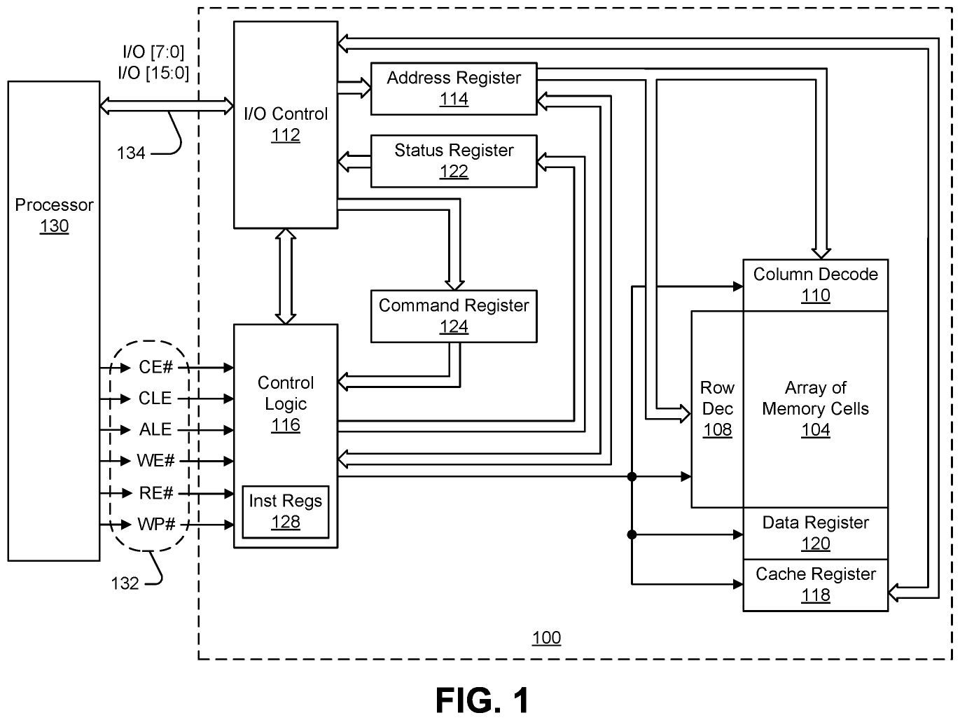

FIG. 1 is a simplified block diagram of a first apparatus, in the form of a memory (e.g., memory device) 100, in communication with a second apparatus, in the form of a processor 130, as part of a third apparatus, in the form of an electronic system, according to an embodiment. Some examples of electronic systems include personal computers, personal digital assistants (PDAs), digital cameras, digital media players, digital recorders, games, appliances, vehicles, wireless devices, mobile telephones and the like. The processor 130, e.g., a controller external to the memory device 100, might be a memory controller or other external host device.

Memory device 100 includes an array of memory cells 104 that might be logically arranged in rows and columns. Memory cells of a logical row are typically connected to the same access line (commonly referred to as a word line) while memory cells of a logical column are typically selectively connected to the same data line (commonly referred to as a bit line). A single access line might be associated with more than one logical row of memory cells and a single data line might be associated with more than one logical column. Memory cells (not shown in FIG. 1) of at least a portion of array of memory cells 104 are capable of being programmed to one of at least two target data states. At least a portion of the memory cells of the array of memory cells 104 might have a structure in accordance with an embodiment.

A row decode circuitry 108 and a column decode circuitry 110 are provided to decode address signals. Address signals are received and decoded to access the array of memory cells 104. Memory device 100 also includes input/output (I/O) control circuitry 112 to manage input of commands, addresses and data to the memory device 100 as well as output of data and status information from the memory device 100. An address register 114 is in communication with I/O control circuitry 112 and row decode circuitry 108 and column decode circuitry 110 to latch the address signals prior to decoding. A command register 124 is in communication with I/O control circuitry 112 and control logic 116 to latch incoming commands.

A controller (e.g., the control logic 116 internal to the memory device 100) controls access to the array of memory cells 104 in response to the commands and might generate status information for the external processor 130, i.e., control logic 116 is configured to perform array operations (e.g., sensing operations [which might include read operations and verify operations], programming operations and/or erase operations) on the array of memory cells 104. The control logic 116 is in communication with row decode circuitry 108 and column decode circuitry 110 to control the row decode circuitry 108 and column decode circuitry 110 in response to the addresses. The control logic 116 might include instruction registers 128 which might represent computer-usable memory for storing computer-readable instructions. For some embodiments, the instruction registers 128 might represent firmware. Alternatively, the instruction registers 128 might represent a grouping of memory cells, e.g., reserved block(s) of memory cells, of the array of memory cells 104.

Control logic 116 might also be in communication with a cache register 118. Cache register 118 latches data, either incoming or outgoing, as directed by control logic 116 to temporarily store data while the array of memory cells 104 is busy writing or reading, respectively, other data. During a programming operation (e.g., write operation), data might be passed from the cache register 118 to the data register 120 for transfer to the array of memory cells 104, then new data might be latched in the cache register 118 from the I/O control circuitry 112. During a read operation, data might be passed from the cache register 118 to the I/O control circuitry 112 for output to the external processor 130, then new data might be passed from the data register 120 to the cache register 118. The cache register 118 and/or the data register 120 might form (e.g., might form a portion of) a page buffer of the memory device 100. A data register 120 might further include sense circuits (not shown in FIG. 1) to sense a data state of a memory cell of the array of memory cells 104, e.g., by sensing a state of a data line connected to that memory cell. A status register 122 might be in communication with I/O control circuitry 112 and control logic 116 to latch the status information for output to the processor 130.

Memory device 100 receives control signals at control logic 116 from processor 130 over a control link 132. The control signals might include a chip enable CE #, a command latch enable CLE, an address latch enable ALE, a write enable WE #, a read enable RE #, and a write protect WP #. Additional or alternative control signals (not shown) might be further received over control link 132 depending upon the nature of the memory device 100. Memory device 100 receives command signals (which represent commands), address signals (which represent addresses), and data signals (which represent data) from processor 130 over a multiplexed input/output (I/O) bus 134 and outputs data to processor 130 over I/O bus 134.

For example, the commands might be received over input/output (I/O) pins [7:0] of I/O bus 134 at I/O control circuitry 112 and might then be written into command register 124. The addresses might be received over input/output (I/O) pins [7:0] of I/O bus 134 at I/O control circuitry 112 and might then be written into address register 114. The data might be received over input/output (I/O) pins [7:0] for an 8-bit device or input/output (I/O) pins [15:0] for a 16-bit device at I/O control circuitry 112 and then might be written into cache register 118. The data might be subsequently written into data register 120 for programming the array of memory cells 104. For another embodiment, cache register 118 might be omitted, and the data might be written directly into data register 120. Data might also be output over input/output (I/O) pins [7:0] for an 8-bit device or input/output (I/O) pins [15:0] for a 16-bit device. Although reference might be made to I/O pins, they might include any conductive nodes providing for electrical connection to the memory device 100 by an external device (e.g., processor 130), such as conductive pads or conductive bumps as are commonly used.

It will be appreciated by those skilled in the art that additional circuitry and signals can be provided, and that the memory device 100 of FIG. 1 has been simplified. It should be recognized that the functionality of the various block components described with reference to FIG. 1 might not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1.

Additionally, while specific I/O pins are described in accordance with popular conventions for receipt and output of the various signals, it is noted that other combinations or numbers of I/O pins (or other I/O node structures) might be used in the various embodiments.

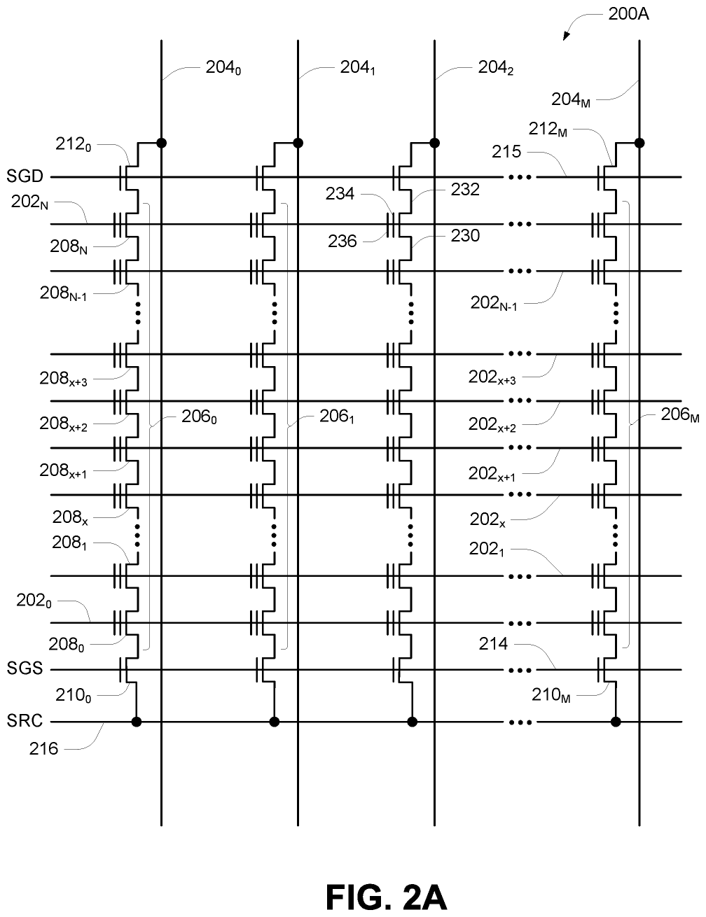

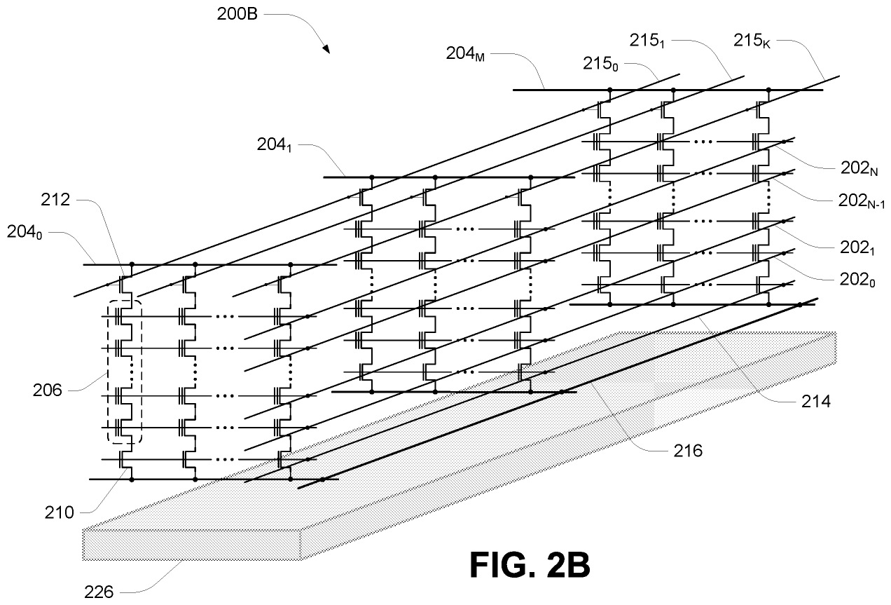

FIG. 2A is a schematic of a portion of an array of memory cells 200A, such as a NAND memory array, as could be used in a memory of the type described with reference to FIG. 1, e.g., as a portion of array of memory cells 104. Memory array 200A includes access lines (e.g., word lines) 202₀ to 202_{N}, and data lines (e.g., bit lines) 204₀ to 204_{M}. The access lines 202 might be connected to global access lines (e.g., global word lines), not shown in FIG. 2A, in a many-to-one relationship. For some embodiments, memory array 200A might be formed over a semiconductor that, for example, might be conductively doped to have a conductivity type, such as a p-type conductivity, e.g., to form a p-well, or an n-type conductivity, e.g., to form an n-well.

Memory array 200A might be arranged in rows (each corresponding to an access line 202) and columns (each corresponding to a data line 204). Each column might include a string of series-connected memory cells (e.g., non-volatile memory cells), such as one of NAND strings 206₀ to 206_{M}. Each NAND string 206 might be connected (e.g., selectively connected) to a common source (SRC) 216 and might include memory cells 208₀ to 208_{N}. The memory cells 208 might represent non-volatile memory cells for storage of data, and might have a structure in accordance with an embodiment. The memory cells 208₀ to 208_{N} might include memory cells intended for storage of data, and might further include other memory cells not intended for storage of data, e.g., dummy memory cells. Dummy memory cells are typically not accessible to a user of the memory, and are instead typically incorporated into the string of series-connected memory cells for operational advantages that are well understood.

The memory cells 208 of each NAND string 206 might be connected in series between a select gate 210 (e.g., a field-effect transistor), such as one of the select gates 210₀ to 210_{M} (e.g., that might be source select transistors, commonly referred to as select gate source), and a select gate 212 (e.g., a field-effect transistor), such as one of the select gates 212₀ to 212_{M} (e.g., that might be drain select transistors, commonly referred to as select gate drain). Select gates 210₀ to 210_{M} might be commonly connected to a select line 214, such as a source select line (SGS), and select gates 212₀ to 212_{M} might be commonly connected to a select line 215, such as a drain select line (SGD). Although depicted as traditional field-effect transistors, the select gates 210 and 212 might utilize a structure similar to (e.g., the same as) the memory cells 208. The select gates 210 and 212 might represent a plurality of select gates connected in series, with each select gate in series configured to receive a same or independent control signal. Although not depicted in FIG. 2A, the select gates 210 and 212 might further represent a combination of select gates and GIDL (gate-induced drain leakage) generator gates connected in series, with each select gate in series configured to receive a same or independent control signal and with each GIDL generator gate in series configured to receive a same or independent control signal.

A source of each select gate 210 might be connected to common source 216. The drain of each select gate 210 might be connected to a memory cell 208₀ of the corresponding NAND string 206. For example, the drain of select gate 210₀ might be connected to memory cell 208₀ of the corresponding NAND string 206₀. Therefore, each select gate 210 might be configured to selectively connect a corresponding NAND string 206 to common source 216. A control gate of each select gate 210 might be connected to select line 214.

The drain of each select gate 212 might be connected to the data line 204 for the corresponding NAND string 206. For example, the drain of select gate 212₀ might be connected to the data line 204₀ for the corresponding NAND string 206₀. The source of each select gate 212 might be connected to a memory cell 208_{N} of the corresponding NAND string 206. For example, the source of select gate 212₀ might be connected to memory cell 208_{N} of the corresponding NAND string 206₀. Therefore, each select gate 212 might be configured to selectively connect a corresponding NAND string 206 to the corresponding data line 204. A control gate of each select gate 212 might be connected to select line 215.

The memory array in FIG. 2A might be a quasi-two-dimensional memory array and might have a generally planar structure, e.g., where the common source 216, NAND strings 206 and data lines 204 extend in substantially parallel planes. Alternatively, the memory array in FIG. 2A might be a three-dimensional memory array, e.g., where NAND strings 206 might extend substantially perpendicular to a plane containing the common source 216 and to a plane containing the data lines 204 that might be substantially parallel to the plane containing the common source 216.

Typical construction of memory cells 208 includes a charge-storage node 234 (e.g., a floating gate, charge trap, or other structure configured to store charge) that can determine a data state of the memory cell (e.g., through changes in threshold voltage), and a control gate 336, as shown in FIG. 2A. The charge-storage structure 234 might include conductive and/or dielectric structures while the control gate 336 is generally formed of one or more conductive materials. In some cases, memory cells 208 might further have a defined source/drain (e.g., source) 230 and a defined source/drain (e.g., drain) 232. Memory cells 208 have their control gates 336 connected to (and in some cases form) an access line 202.

A column of the memory cells 208 might be a NAND string 206 or a plurality of NAND strings 206 selectively connected to a given data line 204. A row of the memory cells 208 might be memory cells 208 commonly connected to a given access line 202. A row of memory cells 208 can, but need not, include all memory cells 208 commonly connected to a given access line 202. Rows of memory cells 208 might often be divided into one or more groups of physical pages of memory cells 208, and physical pages of memory cells 208 often include every other memory cell 208 commonly connected to a given access line 202. For example, memory cells 208 commonly connected to access line 202_{N} and selectively connected to even data lines 204 (e.g., data lines 204₀, 204₂, 204₄, etc.) might be one physical page of memory cells 208 (e.g., even memory cells) while memory cells 208 commonly connected to access line 202_{N} and selectively connected to odd data lines 204 (e.g., data lines 204₁, 204₃, 204₅, etc.) might be another physical page of memory cells 208 (e.g., odd memory cells). Although data lines 204₃-204₅ are not explicitly depicted in FIG. 2A, it is apparent from the figure that the data lines 204 of the array of memory cells 200A might be numbered consecutively from data line 204₀ to data line 204_{M}. Other groupings of memory cells 208 commonly connected to a given access line 202 might also define a physical page of memory cells 208. For certain memory devices, all memory cells commonly connected to a given access line might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells might include those memory cells that are configured to be erased together, such as all memory cells connected to access lines 202₀-202_{N} (e.g., all NAND strings 206 sharing common access lines 202). Unless expressly distinguished, a reference to a page of memory cells herein refers to the memory cells of a logical page of memory cells.

Although the example of FIG. 2A is discussed in conjunction with NAND flash, the embodiments and concepts described herein are not limited to a particular array architecture, and can include other architectures (e.g., AND arrays, NOR arrays, etc.).

FIG. 2B is another schematic of a portion of an array of memory cells 200B as could be used in a memory of the type described with reference to FIG. 1, e.g., as a portion of array of memory cells 104. Like numbered elements in FIG. 2B correspond to the description as provided with respect to FIG. 2A. FIG. 2B provides additional detail of one example of a three-dimensional NAND memory array structure. The three-dimensional NAND memory array 200B might incorporate vertical structures which might include semiconductor pillars, which might be solid or hollow, where a portion of a pillar might act as a channel region of the memory cells of NAND strings 206, e.g., a region through which current might flow when a memory cell, e.g., a field-effect transistor, is activated. The NAND strings 206 might be each selectively connected to a data line 204₀-204_{M} by a select transistor 212 (e.g., that might be drain select transistors, commonly referred to as select gate drain) and to a common source 216 by a select transistor 210 (e.g., that might be source select transistors, commonly referred to as select gate source). Multiple NAND strings 206 might be selectively connected to the same data line 204. Subsets of NAND strings 206 can be connected to their respective data lines 204 by biasing the select lines 215₀-215_{K} to selectively activate particular select transistors 212 each between a NAND string 206 and a data line 204. The select transistors 210 can be activated by biasing the select line 214. Each access line 202 might be connected to multiple rows of memory cells of the memory array 200B. Rows of memory cells that are commonly connected to each other by a particular access line 202 might collectively be referred to as tiers.

The three-dimensional NAND memory array 200B might be formed over peripheral circuitry 226. The peripheral circuitry 226 might represent a variety of circuitry for accessing the memory array 200B. The peripheral circuitry 226 might include complementary circuit elements. For example, the peripheral circuitry 226 might include both n-channel region and p-channel region transistors formed overlying a same semiconductor substrate, a process commonly referred to as CMOS, or complementary metal-oxide-semiconductors. Although CMOS often no longer utilizes a strict metal-oxide-semiconductor construction due to advancements in integrated circuit fabrication and design, the CMOS designation remains as a matter of convenience.

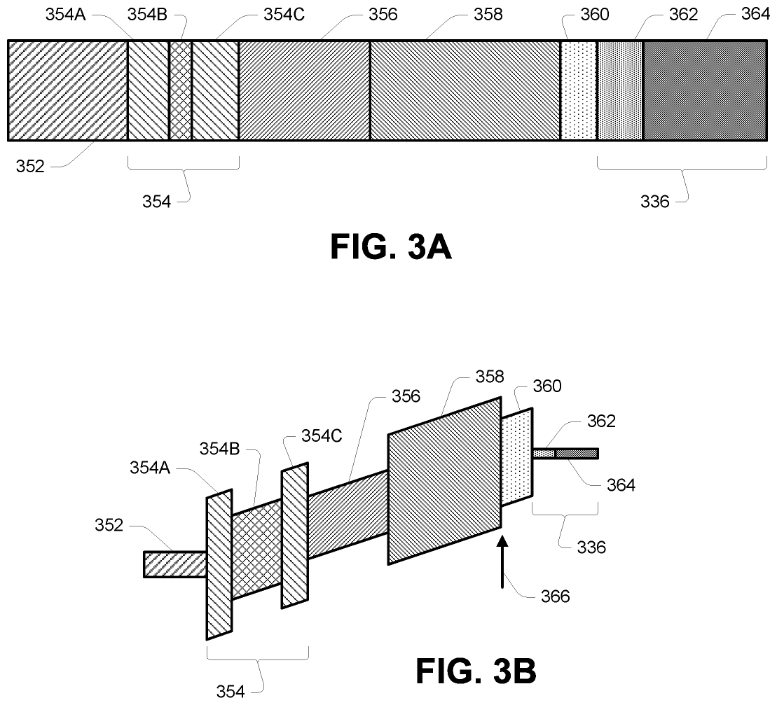

FIG. 3A depicts various components of a memory cell of the related art. As depicted in FIG. 3A, a memory cell might include a channel material (e.g., a semiconductor) 352. The channel material 352 might function as a channel for future memory cells and other transistors having a same structure, and might include one or more semiconductor materials, which might be conductively doped to provide desired threshold voltage characteristics.

The memory cell of FIG. 3A might further include a gate dielectric 354 adjacent to (e.g., immediately adjacent to and/or in direct contact with) the channel material 352. The gate dielectric 354 might include one or more dielectric materials. As one example, the gate dielectric 354 might contain a first instance (354A) of silicon dioxide adjacent to the channel material 352, an instance (354B) of silicon nitride adjacent to the first instance (354A) of silicon dioxide, and a second instance (354C) of silicon dioxide adjacent to the instance (354B) of silicon nitride. Such a structure might be referred to as a band-engineered gate dielectric.

The memory cell of FIG. 3A might further include a charge-storage material 356 adjacent to (e.g., immediately adjacent to and/or in direct contact with) the gate dielectric 354. The charge-storage material 356 might function as a charge-storage node for the memory cell and might include materials capable of storing a charge.

The memory cell of FIG. 3A might further include a charge-blocking material 358 adjacent to (e.g., immediately adjacent to and/or in direct contact with) the charge-storage material 356. The charge-blocking material 358 might function as a charge-blocking node for the memory cell, and might include dielectric material.

The memory cell of FIG. 3A might further include a high-K dielectric 360 adjacent to (e.g., immediately adjacent to and/or in direct contact with) the charge-blocking material 358. The high-K dielectric 360 might contain one or more high-K dielectric materials. High-K dielectric materials as used herein means a material having a dielectric constant greater than that of silicon dioxide.

The memory cell of FIG. 3A might further include a control gate 336 adjacent to (e.g., immediately adjacent to and/or in direct contact with) the high-K dielectric 360. The control gate 336 might be a portion of an access line of an array of memory cells. The control gate 336 might contain one or more conductive materials. In the example of FIG. 3A, the control gate 336 includes a conductive barrier 362 adjacent to (e.g., immediately adjacent to and/or in direct contact with) the high-K dielectric 360, and a conductor 364 adjacent to (e.g., immediately adjacent to and/or in direct contact with) the conductive barrier 362.

FIG. 3B depicts an energy band diagram for the structure of FIG. 3A. FIG. 3B depicts that a dipole layer 366 might be formed at an interface between the charge-blocking material 358 and the high-K dielectric 360 to mitigate back-tunneling of electrons from the control gate 336.

Various embodiments seek to facilitate an improvement in erase saturation characteristics of a memory cell through the addition of a laminated dielectric between a control gate and a charge-blocking layer of the memory cell. The laminated dielectric might include alternating instances of a first dielectric material and of a second dielectric material. The first dielectric material might have a higher oxygen areal density than the second dielectric material. This differential in oxygen areal density might aid in the formation of additional dipole layers in the structure of a memory cell, which can lead to an improvement in erase saturation characteristics. The first dielectric material might further have higher dielectric constant than the second dielectric material.

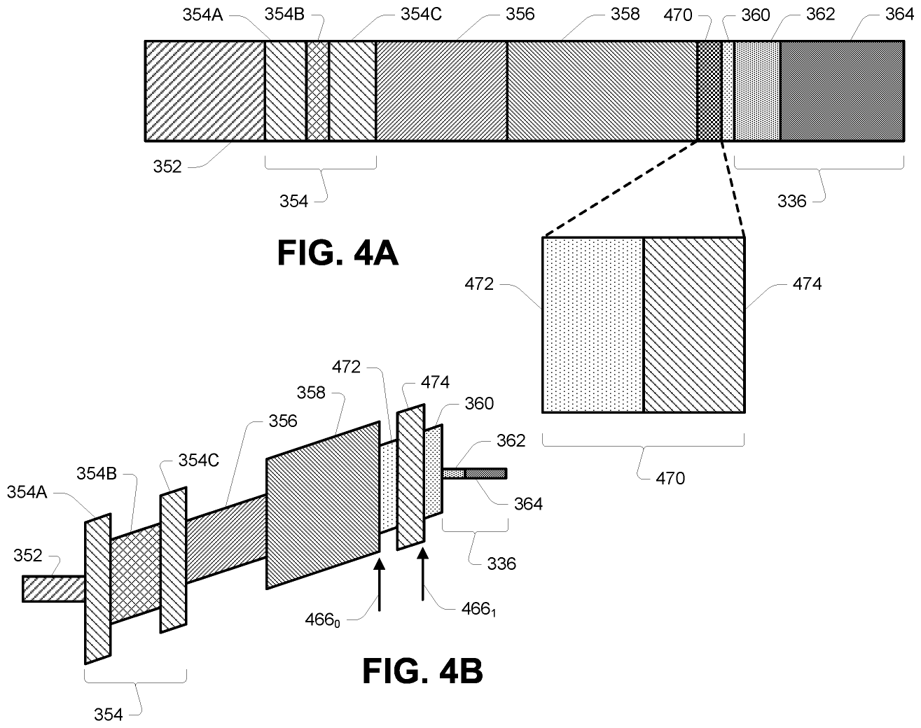

FIG. 4A depicts various components of a memory cell in accordance with an embodiment. As depicted in FIG. 4A, a memory cell might include a channel material (e.g., a semiconductor) 352. The channel material 352 might function as a channel for the memory cell or other transistors having a same structure, and might include one or more semiconductor materials, which might be conductively doped to provide desired threshold voltage characteristics. The channel material 352 might include polycrystalline silicon, commonly referred to as polysilicon. Other semiconductor materials might include amorphous or monocrystalline silicon, or germanium in polycrystalline, amorphous, or monocrystalline forms, for example.

The memory cell of FIG. 4A might further include a gate dielectric 354 adjacent to (e.g., immediately adjacent to and/or in direct contact with) the channel material 352. The gate dielectric 354 might include one or more dielectric materials. The gate dielectric 354 might comprise, consist of, or consist essentially of an oxide, e.g., silicon dioxide (SiO₂), and/or might comprise, consist of, or consist essentially of a high-K dielectric material, such as silicon nitride (Si₃N₄), an aluminum oxide (AlOₓ), a hafnium oxide (HfOₓ), a lanthanum oxide (LaOₓ), scandium(III) oxide (Sc₂O₃), a tantalum oxide (TaOₓ), a zirconium oxide (ZrOₓ), an aluminum hafnium oxide (AlHfOₓ), an aluminum zirconium oxide (AlZrOₓ), a hafnium silicon oxide (HfSiOₓ), a hafnium zirconium oxide (HfZrOₓ), a hafnium aluminum zirconium oxide (HfAlZrOₓ), or yttrium(III) oxide (Y₂O₃), as well as any other dielectric material. As one example, the gate dielectric 354 might contain a first instance (354A) of silicon dioxide adjacent to the channel material 352, an instance (354B) of silicon nitride adjacent to the first instance (354A) of silicon dioxide, and a second instance (354C) of silicon dioxide adjacent to the instance (354B) of silicon nitride.

The memory cell of FIG. 4A might further include a charge-storage material 356 adjacent to (e.g., immediately adjacent to and/or in direct contact with) the gate dielectric 354. The charge-storage material 356 might function as a charge-storage node for the memory cell or other transistors having a same structure, and might include one or more conductive and/or dielectric materials capable of storing a charge. The charge-storage material 356 might further contain both dielectric and conductive materials, e.g., conductive nano-particles in a dielectric bulk material. For charge-storage material 356 containing a conductive material as its bulk, or contiguous, structure, resulting memory cells might typically be referred to as floating-gate memory cells. For charge-storage material 356 containing a dielectric material as its bulk, or contiguous, structure, resulting memory cells might typically be referred to as charge-trap memory cells.

The memory cell of FIG. 4A might further include a charge-blocking material 358 adjacent to (e.g., immediately adjacent to and/or in direct contact with) the charge-storage material 356. The charge-blocking material 358 might function as a charge-blocking node for future memory cells and other transistors having a same structure, and might comprise, consist of, or consist essentially of an oxide, e.g., silicon dioxide (SiO₂), and/or might comprise, consist of, or consist essentially of a high-K dielectric material, such as silicon nitride (Si₃N₄), an aluminum oxide (AlOₓ), a hafnium oxide (HfOₓ), a lanthanum oxide (LaOₓ), scandium(III) oxide (Sc₂O₃), a tantalum oxide (TaOₓ), a zirconium oxide (ZrOₓ), an aluminum hafnium oxide (AlHfOₓ), an aluminum zirconium oxide (AlZrOₓ), a hafnium silicon oxide (HfSiOₓ), a hafnium zirconium oxide (HfZrOₓ), a hafnium aluminum zirconium oxide (HfAlZrOₓ), or yttrium(III) oxide (Y₂O₃), as well as any other dielectric material. As one example, the charge-blocking material 358 might include silicon dioxide. Collectively, the charge-blocking material 358, the charge-storage material 356, and the gate dielectric 354 might be referred to as a data-storage node.

The memory cell of FIG. 4A might further include a laminated dielectric 470 adjacent to (e.g., immediately adjacent to and/or in direct contact with) the charge-blocking material 358. The laminated dielectric 470 contains at least one instance of a first dielectric material 472 and at least one instance of a second dielectric material 474 different than the first dielectric material 472. The embodiment depicted in FIG. 4A contains an instance of the first dielectric material 472 adjacent to (e.g., immediately adjacent to and/or in direct contact with) the charge-blocking material 358, and an instance of the second dielectric material 474 adjacent to (e.g., immediately adjacent to and/or in direct contact with) the instance of the first dielectric material 472. For embodiments of a laminated dielectric 470 having more than one instance of the first dielectric material 472 and/or more than one instance of the second dielectric material 474, the instances of the first dielectric material 472 and the instances of the second dielectric material 474 are arranged in an alternating fashion such that each instance of the first dielectric material 472 is separated from any other instance of the first dielectric material 472 by an instance of the second dielectric material 474, and each instance of the second dielectric material 474 is separated from any other instance of the second dielectric material 474 by an instance of the first dielectric material 472. For some embodiments, each instance of the first dielectric material 472 and each instance of the second dielectric material 474 might have a respective thickness (e.g., measured left to right in FIG. 4A) in a range of 0.5 nm to 5 nm.

The first dielectric material 472 has an oxygen areal density that is higher than an oxygen areal density of the second dielectric material 474. For some embodiments, each instance of the first dielectric material 472 of a laminated dielectric 470 contains a same dielectric material. For some embodiments, each instance of the second dielectric material 474 of a laminated dielectric 470 contains a same dielectric material. However, different instances of the first dielectric material 472 of a laminated dielectric 470 could utilize different dielectric materials provided that each instance of the first dielectric material 472 has a higher oxygen areal density than each immediately adjacent instance of the second dielectric material 474 of the laminated dielectric 470, and different instances of the second dielectric material 474 of a laminated dielectric 470 could utilize different dielectric materials provided that each instance of the second dielectric material 474 has a lower oxygen areal density than each immediately adjacent instance of the first dielectric material 472 of the laminated dielectric 470.

In FIG. 4A, an electric dipole layer might be formed at the interface between the instance of the first dielectric material 472 and the instance of the second dielectric material 474 due to the oxygen density difference. The dipole layer formation may be driven by the migration or displacement of negatively charged oxygen ions from the material with the higher oxygen density to the material with the lower oxygen density. This dipole layer might induce flat band voltage (V_{fb}) shift, which might facilitate an increase of potential barrier between the control gate and the channel of a memory cell and an increase of the effective work function (eWF) of a metal control gate. As a result, erase saturation characteristics might be improved. Embodiments incorporating more than one instance of the first dielectric material 472 and more than one instance of the second dielectric material 474 might further improve this Vfb shift and erase saturation characteristics by forming additional dipole layers.

Examples of dielectric material for instances of the first dielectric material 472 might include scandium(III) oxide (Sc₂O₃), magnesium oxide (MgO), zirconium dioxide (ZrO₂), hafnium dioxide (HfO₂), tantalum pentoxide (Ta₂O₅), titanium dioxide (TiO₂), and aluminum(III) oxide (Al₂O₃), although other dielectric materials could also be used. Examples of dielectric material for instances of the second dielectric material 474 might include silicon dioxide (SiO₂) and germanium dioxide (GeO₂), although other dielectric materials could also be used. For some embodiments, the oxygen areal density of the first dielectric material 472 is greater than or equal to 20% higher than the oxygen areal density of the second dielectric material 474. Higher differentials in oxygen areal density might be expected to produce higher levels of effect of the formed dipole layer.

The memory cell of FIG. 4A might further include a high-K dielectric 360 adjacent to (e.g., immediately adjacent to and/or in direct contact with) the laminated dielectric 470. The high-K dielectric 360 might contain one or more high-K dielectric materials. For example, the high-K dielectric 360 might comprise, consist of, or consist essentially of a high-K dielectric material, such as an aluminum oxide (AlOₓ), a hafnium oxide (HfOₓ), a lanthanum oxide (LaOₓ), scandium(III) oxide (Sc₂O₃), a tantalum oxide (TaOₓ), a zirconium oxide (ZrOₓ), an aluminum hafnium oxide (AlHfOₓ), an aluminum zirconium oxide (AlZrOₓ), a hafnium silicon oxide (HfSiOₓ), a hafnium zirconium oxide (HfZrOₓ), a hafnium aluminum zirconium oxide (HfAlZrOₓ), or yttrium(III) oxide (Y₂O₃), as well as any other high-K dielectric material. The high-K dielectric 360 might be a different dielectric material than one or more, which might include all, instances of the first dielectric material 472. Alternatively, the high-K dielectric 360 might be a same dielectric material as one or more, which might include all, instances of the first dielectric material 472. For some embodiments, the high-K dielectric 360 might have a higher oxygen areal density than an instance of the second dielectric material 474 adjacent to (e.g., immediately adjacent to and/or in direct contact with) the high-K dielectric 360. For some embodiments, the high-K dielectric 360 comprises a dielectric material selected from a group consisting of aluminum(III) oxide (Al₂O₃), a hafnium oxide (HfOₓ), scandium(III) oxide (Sc₂O₃), tantalum pentoxide (Ta₂O₅), a zirconium oxide (ZrOₓ), an aluminum hafnium oxide (AlHfOₓ), an aluminum zirconium oxide (AlZrOₓ), a hafnium zirconium oxide (HfZrOₓ), and a hafnium aluminum zirconium oxide (HfAlZrOₓ).

The memory cell of FIG. 4A might further include a control gate 336 adjacent to (e.g., immediately adjacent to and/or in direct contact with) the high-K dielectric 360. The control gate 336 might be a portion of an access line of an array of memory cells. The control gate 336 might contain one or more conductive materials. The control gate 336 might comprise, consist of, or consist essentially of conductively doped polysilicon. Alternatively or in addition, the control gate 336 might comprise, consist of, or consist essentially of metal, such as a refractory metal, or a metal-containing material, such as a refractory metal silicide or a metal nitride, e.g., a refractory metal nitride, as well as any other conductive material. The metals of chromium (Cr), cobalt (Co), hafnium (Hf), molybdenum (Mo), niobium (Nb), tantalum (Ta), titanium (Ti), tungsten (W), vanadium (V) and zirconium (Zr) are generally recognized as refractory metals. In the example of FIG. 4A, the control gate 336 includes a conductive barrier 362 adjacent to (e.g., immediately adjacent to and/or in direct contact with) the high-K dielectric 360, and a conductor 364 adjacent to (e.g., immediately adjacent to and/or in direct contact with) the conductive barrier 362. For example, the conductive barrier 362 might contain titanium nitride, and the conductor 364 might contain tungsten.

FIG. 4B depicts an energy band diagram for the structure of FIG. 4A. FIG. 4B depicts that a first dipole layer 466₀ might be formed at an interface between the charge-blocking material 358 and an instance of the first dielectric material 472, and a second dipole layer 466₁ might be formed at an interface between an instance of the second dielectric material 474 and the high-K dielectric 360 to mitigate back-tunneling of electrons from the control gate 336. Additional dipole layers (not shown in FIG. 4B) might be formed by inserting additional alternating instances of the first dielectric material 472 and of the second dielectric material 474 in the laminated dielectric 470.

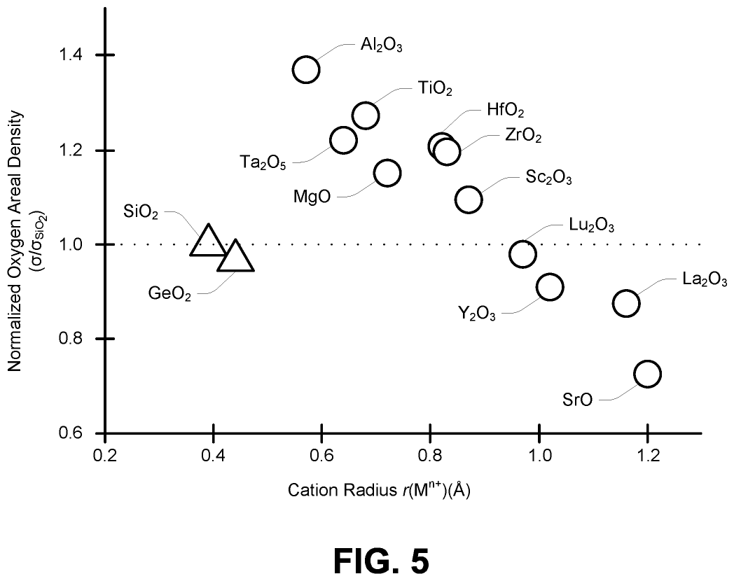

FIG. 5 depicts a graph of normalized oxygen areal density as a function of cation radius of a number of dielectric materials that might be suitable candidates for the instances of the first dielectric material 472 and for the instances of the second dielectric material 474. The values of oxygen areal density are normalized to the oxygen areal density of silicon dioxide having a value of 1. Using the example of silicon dioxide as an instance of the second dielectric material 474, and only looking to dielectric materials represented in FIG. 5, an adjacent (e.g., immediately adjacent) instance of the first dielectric material 472 might be selected from a group of dielectric materials including scandium(III) oxide (Sc₂O₃), magnesium oxide (MgO), zirconium dioxide (ZrO₂), hafnium dioxide (HfO₂), tantalum pentoxide (Ta₂O₅), titanium dioxide (TiO₂), and aluminum(III) oxide (Al₂O₃). Continuing the example, and further restricting the dielectric materials represented in FIG. 5 to those having an oxygen areal density of greater than or equal to 20% higher than the oxygen areal density of silicon dioxide, the adjacent (e.g., immediately adjacent) instance of the first dielectric material 472 might be selected from a group of dielectric materials including hafnium dioxide (HfO₂), tantalum pentoxide (Ta₂O₅), titanium dioxide (TiO₂), and aluminum(III) oxide (Al₂O₃).

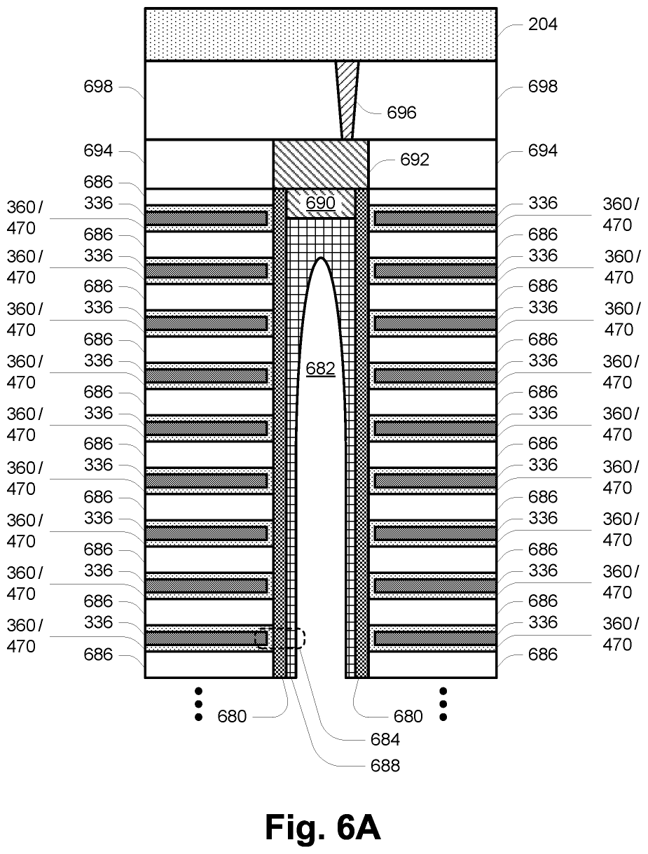

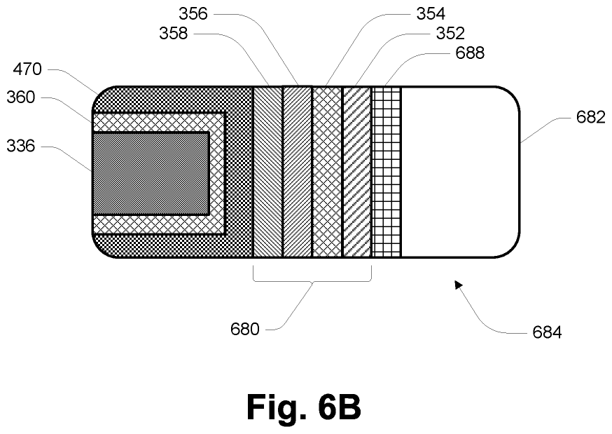

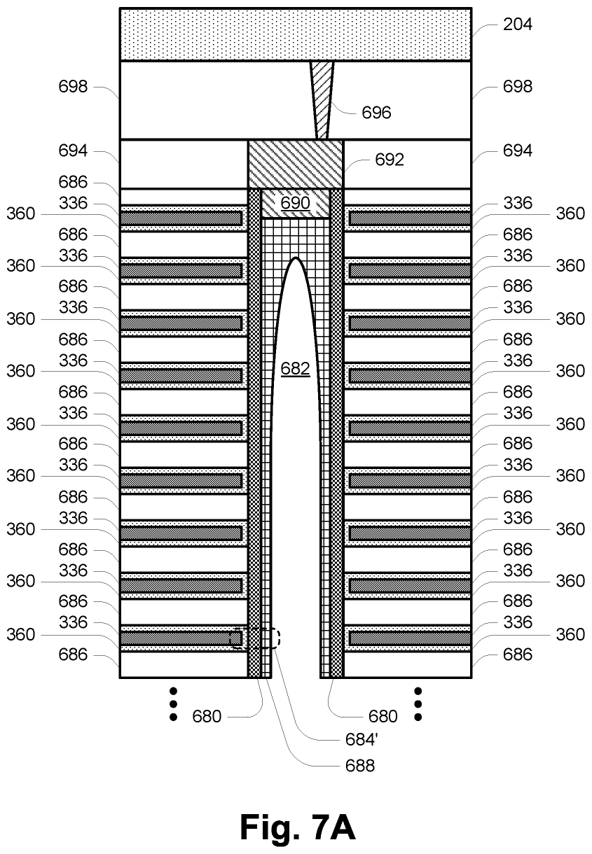

FIG. 6A depicts a cross-sectional view of a memory array structure to aid description of various embodiments. For example, the memory array structure might correspond to a portion (e.g., upper or drain-side portion) of a string of series-connected memory cells and corresponding drain select gates depicting connectivity to a data line. FIG. 6B depicts an exploded portion of the memory array structure of FIG. 6A providing additional detail of a memory cell structure within the memory array structure. Like numbered elements in FIGS. 6A-6B correspond to the description as provided with respect to FIG. 4A.

As noted, memory cells and select gates might utilize a same structure, e.g., the structure of a programmable field-effect transistor (FET). These transistors might be formed from alternating layers of conductive materials and dielectric materials, formed around a pillar that acts as a common channel for the transistors, and which might be hollow.

In FIG. 6A, a transistor might be formed at each intersection of a control gate 336 and a channel-material structure 680. Although the channel-material structure 680 in FIG. 6A is depicted as a hollow pillar containing a void 682, the channel-material structure 680 could alternatively be a solid pillar. The channel-material structure 680 might include a charge-blocking material 358, a charge-storage material 356, a gate dielectric 354, and a channel material 352. The portion 684 is depicted in further detail in FIG. 6B. The instances of control gates 336 might be isolated from one another by instances of a dielectric 686.

Each instance of control gate 336 might be formed of one or more conductive materials. A control gate 336 might comprise, consist of, or consist essentially of conductively doped polysilicon. Alternatively or in addition, each control gate 336 might comprise, consist of, or consist essentially of metal, such as a refractory metal, or a metal-containing material, such as a refractory metal silicide or a metal nitride, e.g., a refractory metal nitride, as well as any other conductive material.

Each instance of dielectric 686 might be formed of one or more dielectric materials. A dielectric 686 might comprise, consist of, or consist essentially of an oxide, e.g., silicon dioxide (SiO₂), and/or might comprise, consist of, or consist essentially of a high-K dielectric material, such as silicon nitride (Si₃N₄), an aluminum oxide (AlOₓ), a hafnium oxide (HfOₓ), a lanthanum oxide (LaOₓ), scandium(III) oxide (Sc₂O₃), a tantalum oxide (TaOₓ), a zirconium oxide (ZrOₓ), an aluminum hafnium oxide (AlHfOₓ), an aluminum zirconium oxide (AlZrOₓ), a hafnium silicon oxide (HfSiOₓ), a hafnium zirconium oxide (HfZrOₓ), a hafnium aluminum zirconium oxide (HfAlZrOₓ), or yttrium(III) oxide (Y₂O₃), as well as any other dielectric material. A dielectric 686 might further comprise, consist of, or consist essentially of a spin-on dielectric material, e.g., hydrogen silsesquioxane (HSQ), hexamethyldisiloxane, octamethyltrisiloxane, etc., or a high-density-plasma (HDP) oxide. As one example, the dielectric 686 might contain silicon dioxide.

For embodiments utilizing a hollow channel-material structure 680, a dielectric 688 might be formed inside the channel-material structure 680 to close access to the void 682 from subsequently formed materials. The dielectric 688 might comprise, consist of, or consist essentially of an oxide, e.g., silicon dioxide (SiO₂). The dielectric 688 might further comprise, consist of, or consist essentially of a spin-on dielectric material, e.g., hydrogen silsesquioxane (HSQ), hexamethyldisiloxane, octamethyltrisiloxane, etc., or a high-density-plasma (HDP) oxide. The dielectric 688 might further comprise, consist of, or consist essentially of any other dielectric material. The dielectric 688 might contain one or more dielectric materials that can be selectively removed without adversely affecting the materials of the instances of dielectric 686, the materials of the channel-material structure 680. Although depicted to be in contact with the entire length of the depicted channel-material structure 680, the dielectric 688 might not extend a full length of the channel-material structure 680. For example, the dielectric 688 might pinch off at the top of the void 682 before sufficient dielectric 688 can enter lower portions of the void 682.

A conductive plug 690 might be formed overlying the dielectric 688 to be electrically connected to the channel material 352 of the channel-material structure 680. The conductive plug 690 might contain one or more conductive materials. The conductive plug 690 might comprise, consist of, or consist essentially of conductively doped polysilicon and/or might comprise, consist of, or consist essentially of metal, such as a refractory metal, or a metal-containing material, such as a refractory metal silicide or a metal nitride, e.g., a refractory metal nitride, as well as any other conductive material. For some embodiments, the conductive plug 690 might contain an n⁺-type conductively-doped polysilicon.

As depicted in FIG. 6B, the channel-material structure 680 of the portion 684 might include a charge-blocking material 358 formed adjacent to, and surrounded by, the instances of control gates 336 and dielectrics 686, e.g., overlying the sidewalls of the void 682. For example, the charge-blocking material 358 might be formed overlying sidewalls of the void 682. A charge-storage material 356 might be formed overlying the charge-blocking material 358, a gate dielectric 354 might be formed overlying the charge-storage material 356, and a channel material (e.g., a semiconductor) 352 might be formed overlying the gate dielectric 354. The channel material 352 might be a portion of a contiguous semiconductor structure for each transistor formed around the channel-material structure 680, or might otherwise be electrically connected, which might include selectively electrically connected, to channels of each such transistor. The channel material 352 might have a conductivity type, e.g., a p-type conductivity or an n-type conductivity. For some embodiments, the channel material 352 might contain an n⁺-type conductively-doped polysilicon. For embodiments utilizing a solid channel-material structure 680, the channel material 352 might be formed to fill the void 682, and the dielectric 688 might be eliminated. For embodiments utilizing a hollow channel-material structure 680, the dielectric 688 might be formed overlying at least a portion of the channel material 352.

A laminated dielectric 470 might be formed to be adjacent the charge-blocking material 358, a high-K dielectric 360 might be formed to be adjacent to the laminated dielectric 470, and a control gate 336 might be formed to be adjacent to the high-K dielectric 360. Although not depicted in FIGS. 6A-6B, each instance of the control gate 336 might include more than one conductive layer, such as depicted in FIG. 4A. For example, for a control gate 336, a conductive barrier might be formed to be adjacent to the high-K dielectric 360, and a conductor might be formed to be adjacent to the conductive barrier. Continuing with the example, the conductive barrier might contain titanium nitride, and the conductor might contain tungsten.

A contact (e.g., contact plug) 692 might be formed in a dielectric 694, and might be overlying and in physical contact with the channel-material structure 680, and in electrical contact with its channel material 352. The contact 692 might be further overlying and in electrical contact with the conductive plug 690. The contact 692 might contain one or more conductive materials, such as described with reference to the control gates 336. As one example, the contact 692 might comprise, consist of, or consist essentially of a conductively-doped semiconductor material, such as conductively-doped polysilicon. The dielectric 694 might contain one or more dielectric materials, such as described with reference to the dielectric 686. As one example, the dielectric 694 might comprise, consist of, or consist essentially of silicon dioxide.

A contact (e.g., contact via) 696 might be formed in a dielectric 698, and might be overlying and in electrical contact with the contact 692. The contact 696 might further be in physical contact with the contact 692. The contact 696 might contain one or more conductive materials, such as described with reference to the control gates 336. As one example, the contact 696 might comprise, consist of, or consist essentially of a conductively-doped semiconductor material, such as conductively-doped polysilicon. For example, the contact 692 and the contact 696 might both contain conductively-doped polysilicon of a same conductivity type. Alternatively or in addition, the contact 696 might comprise, consist of, or consist essentially of metal, such as a refractory metal, or a metal-containing material, such as a refractory metal silicide or a metal nitride, e.g., a refractory metal nitride, as well as any other conductive material. The dielectric 698 might contain one or more dielectric materials, such as described with reference to the dielectric 686. As one example, the dielectric 698 might comprise, consist of, or consist essentially of silicon dioxide.

A data line 204 might be formed to be overlying and in electrical contact with the contact 696. The data line 204 might further be in physical contact with the contact 696. The data line 204 might contain one or more conductive materials, such as described with reference to the control gates 336. As one example, the data line 204 might comprise, consist of, or consist essentially of a refractory metal, such as tungsten.

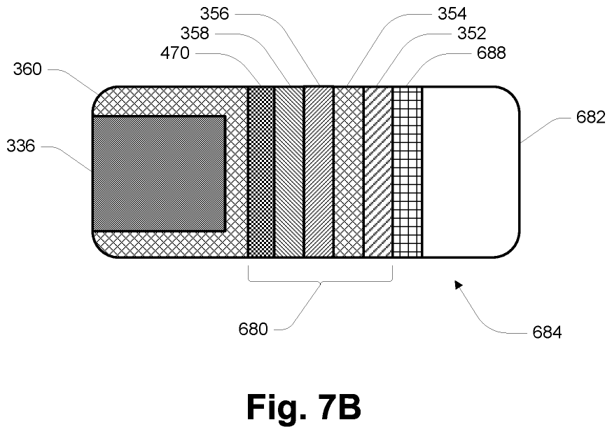

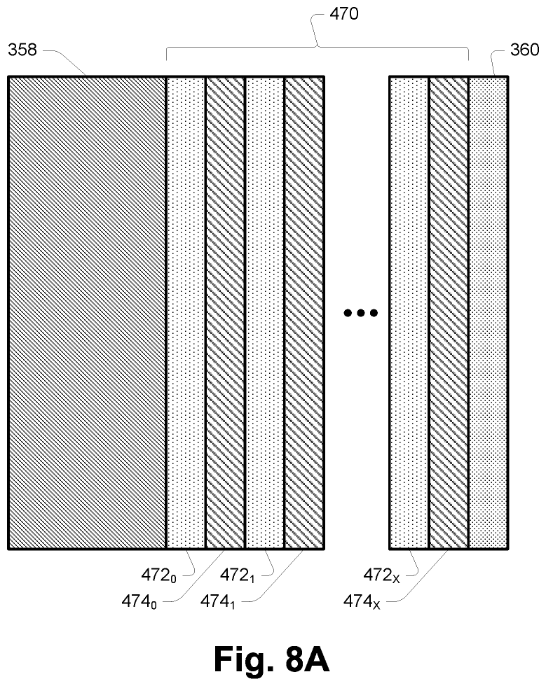

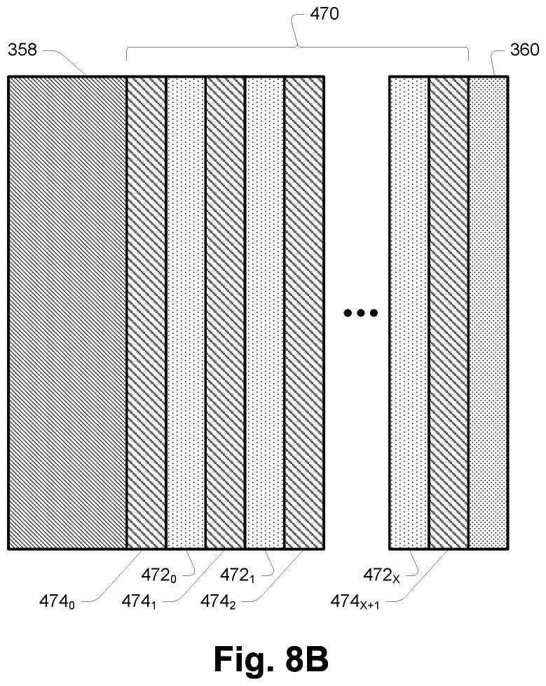

In FIGS. 6A-6B, the laminated dielectric 470 is formed to surround the control gate 336. Alternatively, the laminated dielectric 470 might be formed as part of the channel-material structure 680. FIGS. 7A-7B depict placing the laminated dielectric 470 within the channel-material structure 680.

FIG. 7A depicts a cross-sectional view of a memory array structure to aid description of various embodiments. For example, the memory array structure might correspond to a portion (e.g., upper or drain-side portion) of a string of series-connected memory cells and corresponding drain select gates depicting connectivity to a data line. FIG. 7B depicts an exploded portion of the memory array structure of FIG. 7A providing additional detail of a memory cell structure within the memory array structure. Like numbered elements in FIGS. 7A-7B correspond to the description as provided with respect to FIGS. 6A-6B.

In FIG. 7A, a transistor might be formed at each intersection of a control gate 336 and a channel-material structure 680. Although the channel-material structure 680 in FIG. 7A is depicted as a hollow pillar containing a void 682, the channel-material structure 680 could alternatively be a solid pillar. The channel-material structure 680 might include a laminated dielectric 470, a charge-blocking material 358, a charge-storage material 356, a gate dielectric 354, and a channel material 352. The portion 684′ is depicted in further detail in FIG. 7B. The instances of control gates 336 might be isolated from one another by instances of a dielectric 686.

Each instance of control gate 336 might be formed of one or more conductive materials. A control gate 336 might comprise, consist of, or consist essentially of conductively doped polysilicon. Alternatively or in addition, each control gate 336 might comprise, consist of, or consist essentially of metal, such as a refractory metal, or a metal-containing material, such as a refractory metal silicide or a metal nitride, e.g., a refractory metal nitride, as well as any other conductive material.

Each instance of dielectric 686 might be formed of one or more dielectric materials. A dielectric 686 might comprise, consist of, or consist essentially of an oxide, e.g., silicon dioxide (SiO₂), and/or might comprise, consist of, or consist essentially of a high-K dielectric material, such as silicon nitride (Si₃N₄), an aluminum oxide (AlOₓ), a hafnium oxide (HfOₓ), a lanthanum oxide (LaOₓ), scandium(III) oxide (Sc₂O₃), a tantalum oxide (TaOₓ), a zirconium oxide (ZrOₓ), an aluminum hafnium oxide (AlHfOₓ), an aluminum zirconium oxide (AlZrOₓ), a hafnium silicon oxide (HfSiOₓ), a hafnium zirconium oxide (HfZrOₓ), a hafnium aluminum zirconium oxide (HfAlZrOₓ), or yttrium(III) oxide (Y₂O₃), as well as any other dielectric material. A dielectric 686 might further comprise, consist of, or consist essentially of a spin-on dielectric material, e.g., hydrogen silsesquioxane (HSQ), hexamethyldisiloxane, octamethyltrisiloxane, etc., or a high-density-plasma (HDP) oxide. As one example, the dielectric 686 might contain silicon dioxide.

For embodiments utilizing a hollow channel-material structure 680, a dielectric 688 might be formed inside the channel-material structure 680 to close access to the void 682 from subsequently formed materials. The dielectric 688 might comprise, consist of, or consist essentially of an oxide, e.g., silicon dioxide (SiO₂). The dielectric 688 might further comprise, consist of, or consist essentially of a spin-on dielectric material, e.g., hydrogen silsesquioxane (HSQ), hexamethyldisiloxane, octamethyltrisiloxane, etc., or a high-density-plasma (HDP) oxide. The dielectric 688 might further comprise, consist of, or consist essentially of any other dielectric material. The dielectric 688 might contain one or more dielectric materials that can be selectively removed without adversely affecting the materials of the instances of dielectric 686, the materials of the channel-material structure 680. Although depicted to be in contact with the entire length of the depicted channel-material structure 680, the dielectric 688 might not extend a full length of the channel-material structure 680. For example, the dielectric 688 might pinch off at the top of the void 682 before sufficient dielectric 688 can enter lower portions of the void 682.

A conductive plug 690 might be formed overlying the dielectric 688 to be electrically connected to the channel material 352 of the channel-material structure 680. The conductive plug 690 might contain one or more conductive materials. The conductive plug 690 might comprise, consist of, or consist essentially of conductively doped polysilicon and/or might comprise, consist of, or consist essentially of metal, such as a refractory metal, or a metal-containing material, such as a refractory metal silicide or a metal nitride, e.g., a refractory metal nitride, as well as any other conductive material. For some embodiments, the conductive plug 690 might contain an n⁺-type conductively-doped polysilicon.

As depicted in FIG. 7B, the channel-material structure 680 of the portion 684′ might include a laminated dielectric 470 formed adjacent to, and surrounded by, the instances of control gates 336 and dielectrics 686. For example, the laminated dielectric 470 might be formed overlying sidewalls of the void 682. A charge-blocking material 358 might be formed overlying the laminated dielectric 470, a charge-storage material 356 might be formed overlying the charge-blocking material 358, a gate dielectric 354 might be formed overlying the charge-storage material 356, and a channel material (e.g., a semiconductor) 352 might be formed overlying the gate dielectric 354. The channel material 352 might be a portion of a contiguous semiconductor structure for each transistor formed around the channel-material structure 680, or might otherwise be electrically connected, which might include selectively electrically connected, to channels of each such transistor. The channel material 352 might have a conductivity type, e.g., a p-type conductivity or an n-type conductivity. For some embodiments, the channel material 352 might contain an n″-type conductively-doped polysilicon. For embodiments utilizing a solid channel-material structure 680, the channel material 352 might be formed to fill the void 682, and the dielectric 688 might be eliminated. For embodiments utilizing a hollow channel-material structure 680, the dielectric 688 might be formed overlying at least a portion of the channel material 352.

The high-K dielectric 360 might be formed to be adjacent to the laminated dielectric 470, and the control gate 336 might be formed to be adjacent to the high-K dielectric 360. Although not depicted in FIGS. 7A-7B, each instance of the control gate 336 might include more than one conductive layer, such as depicted in FIG. 4A. For example, for a control gate 336, a conductive barrier might be formed to be adjacent to the high-K dielectric 360, and a conductor might be formed to be adjacent to the conductive barrier. Continuing with the example, the conductive barrier might contain titanium nitride, and the conductor might contain tungsten.

A contact (e.g., contact plug) 692 might be formed in a dielectric 694, and might be overlying and in physical contact with the channel-material structure 680, and in electrical contact with its channel material 352. The contact 692 might be further overlying and in electrical contact with the conductive plug 690. The contact 692 might contain one or more conductive materials, such as described with reference to the control gates 336. As one example, the contact 692 might comprise, consist of, or consist essentially of a conductively-doped semiconductor material, such as conductively-doped polysilicon. The dielectric 694 might contain one or more dielectric materials, such as described with reference to the dielectric 686. As one example, the dielectric 694 might comprise, consist of, or consist essentially of silicon dioxide.

A contact (e.g., contact via) 696 might be formed in a dielectric 698, and might be overlying and in electrical contact with the contact 692. The contact 696 might further be in physical contact with the contact 692. The contact 696 might contain one or more conductive materials, such as described with reference to the control gates 336. As one example, the contact 696 might comprise, consist of, or consist essentially of a conductively-doped semiconductor material, such as conductively-doped polysilicon. For example, the contact 692 and the contact 696 might both contain conductively-doped polysilicon of a same conductivity type. Alternatively or in addition, the contact 696 might comprise, consist of, or consist essentially of metal, such as a refractory metal, or a metal-containing material, such as a refractory metal silicide or a metal nitride, e.g., a refractory metal nitride, as well as any other conductive material. The dielectric 698 might contain one or more dielectric materials, such as described with reference to the dielectric 686. As one example, the dielectric 698 might comprise, consist of, or consist essentially of silicon dioxide.

A data line 204 might be formed to be overlying and in electrical contact with the contact 696. The data line 204 might further be in physical contact with the contact 696. The data line 204 might contain one or more conductive materials, such as described with reference to the control gates 336. As one example, the data line 204 might comprise, consist of, or consist essentially of a refractory metal, such as tungsten.

Although the embodiment of FIGS. 6A-6B placed the laminated dielectric either entirely outside of the channel-material structure 680, and the embodiment of FIGS. 7A-7B placed the laminated dielectric either entirely within the channel-material structure 680, a combination could be used. For example, a portion of the structure of a laminated dielectric 470 might be formed within the channel-material structure 680 as depicted in FIG. 7B, and a remaining portion of the structure of the laminated dielectric 470 might be formed outside of the channel-material structure 680 as depicted in FIG. 6B.

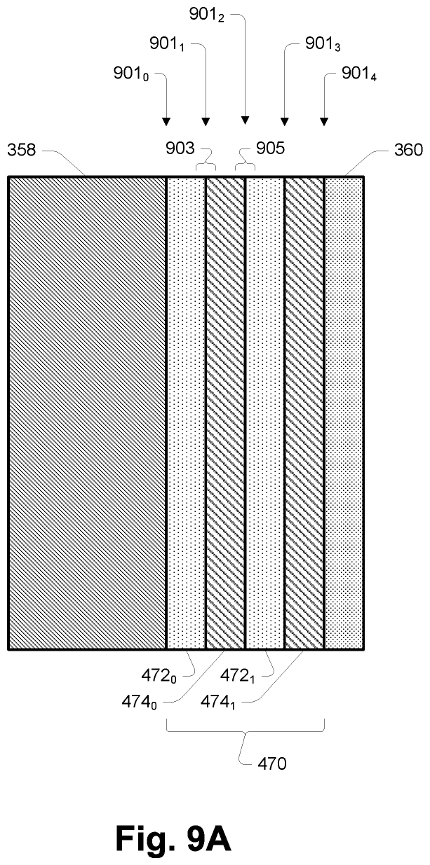

FIG. 8A depicts various components of a memory cell in accordance with an embodiment. FIG. 8A depicts an example of a laminated dielectric 470 including more than one instance of the first dielectric material 472 and more than one instance of the second dielectric material 474. As depicted in FIG. 8A, the laminated dielectric 470 includes X+1 instances of the first dielectric material 472 and X+1 instances of the second dielectric material 474. The value X might be any integer value greater than or equal to one.

FIG. 8B depicts various components of a memory cell in accordance with another embodiment. For embodiments where dipole layer formation is not anticipated at an interface between the charge-blocking material 358 and an immediately adjacent instance of the first dielectric material 472, an instance of the second dielectric material 474 might be formed between the charge-blocking material 358 and the instance of the first dielectric material 472. FIG. 8B depicts such an embodiment. FIG. 8B depicts an example of a laminated dielectric 470 including more than one instance of the first dielectric material 472 and more than one instance of the second dielectric material 474. As depicted in FIG. 8B, the laminated dielectric 470 includes X+1 instances of the first dielectric material 472 and X+2 instances of the second dielectric material 474. The value X might be any integer value greater than or equal to zero.

While a dipole layer might be formed at an interface from an instance of the second dielectric material 474 to an instance of the first dielectric material 472 in a direction toward the control gate 336 (e.g., left to right in FIGS. 8A-8B), an opposite dipole layer might be formed at an interface from the instance of the second dielectric material 474 to an instance of the first dielectric material 472 in a direction away from the control gate 336 (e.g., right to left in FIGS. 8A-8B). The formation of opposite dipole layers on both sides of an instance of the second dielectric material 474 could be counter-productive to improving erase saturation characteristics. However, formation of an opposite dipole layer might be mitigated by forming the interfaces to have characteristics favorable to dipole layer formation when transitioning from an instance of the second dielectric material 474 to an instance of the first dielectric material 472 in a direction toward the control gate 336, and to have characteristics less favorable to dipole layer formation when transitioning from an instance of the first dielectric material 472 to an instance of the second dielectric material 474 in the direction toward the control gate 336. For example, a transition from the second dielectric material 474 to the first dielectric material 474 might be more abrupt for one case than the other in terms of concentration of materials and/or in terms of surface roughness.

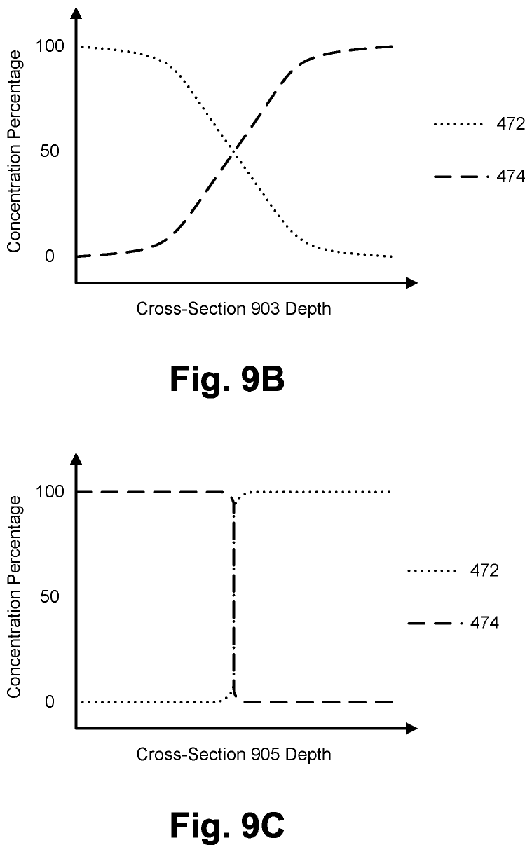

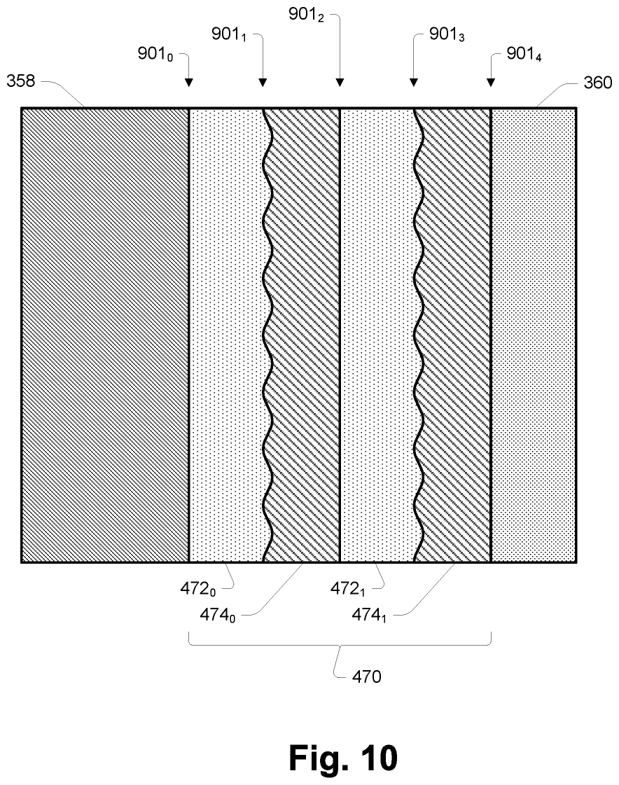

FIG. 9A depicts different interfaces of an embodiment for use in discussing differences in concentration of dielectric materials across interfaces. The example of FIG. 9A depicts a laminated dielectric 470 containing two instances of the first dielectric material 472, e.g., instances of the first dielectric material 472₀ and 472₁, and two instances of the second dielectric material 474, e.g., instances of the second dielectric material 474₀ and 474₁. In the example of FIG. 9A, there might be a first interface 901₀ between the charge-blocking material 358 and the first instance of the first dielectric material 472₀, a second interface 901₁ between the first instance of the first dielectric material 472₀ and the first instance of the second dielectric material 474₀, a third interface 901₂ between the first instance of the second dielectric material 474₀ and the second instance of the first dielectric material 472₁, a fourth interface 901₃ between the second instance of the first dielectric material 472₁ and the second instance of the second dielectric material 474₁, and a fifth interface 901₄ between the second instance of the second dielectric material 474₁ and the high-K dielectric 360.

In FIG. 9A, a cross-section 903 of the second interface 901₁ might have a depth, e.g., left to right in FIG. 9A, and a cross-section 905 of the third interface 901₂ might have a depth, e.g., left to right in FIG. 9A. FIG. 9B depicts a graph of concentration of the first dielectric material 472 and of the second dielectric material 474 across the cross-section 903 of the second interface 901₁. To produce a concentration profile such as depicted in FIG. 9B, a formation rate of the first dielectric material 472 might be reduced gradually while a formation rate of the second dielectric material 474 might be increased gradually. FIG. 9C depicts a graph of concentration of the first dielectric material 472 and of the second dielectric material 474 across the cross-section 905 of the third interface 901₂. To produce a concentration profile such as depicted in FIG. 9C, a formation rate of the second dielectric material 474 might be reduced abruptly while a formation rate of the first dielectric material 472 might be increased abruptly, or the formation of the second dielectric material 474 might be stopped before initiating formation of the first dielectric material 472. The fourth interface 901₃ might have a concentration profile similar to the graph of FIG. 9B, e.g., similar to the second interface 901₁. The first interface 901₀ and the fifth interface 901₄ might have concentration profiles of their respective materials that might be similar to the graph of FIG. 9C, similar to the third interface 901₂.

FIG. 10 depicts different interfaces of an embodiment for use in discussing differences in surface roughness of interfaces. The example of FIG. 10 depicts a laminated dielectric 470 containing two instances of the first dielectric material 472, e.g., instances of the first dielectric material 472₀ and 472₁, and two instances of the second dielectric material 474, e.g., instances of the second dielectric material 474₀ and 474₁. In the example of FIG. 10, there might be a first interface 907₀ between the charge-blocking material 358 and the first instance of the first dielectric material 472₀, a second interface 901₁ between the first instance of the first dielectric material 472₀ and the first instance of the second dielectric material 474₀, a third interface 901₂ between the first instance of the second dielectric material 474₀ and the second instance of the first dielectric material 472₁, a fourth interface 901₃ between the second instance of the first dielectric material 472₁ and the second instance of the second dielectric material 474₁, and a fifth interface 901₄ between the second instance of the second dielectric material 474₁ and the high-K dielectric 360.

In FIG. 10, the second interface 901₁ might have a first level of surface roughness, illustrated conceptually as a wavy line, while the third interface 901₂ might have a second level of surface roughness, lower than the first level of surface roughness, illustrated conceptually as a straight line. Lower levels of surface roughness might be associated with more favorable conditions for formation of a dipole layer than higher levels of surface roughness. The fourth interface 901₃ might have a level of surface roughness similar to the level of surface roughness of the second interface 901₁. The first interface 901₀ and the fifth interface 901₄ might have levels of surface roughness similar to the level of surface roughness of the third interface 901₂. Variations of surface roughness might be produced by changing reaction conditions, e.g., pressure and/or temperature, during formation of the materials.

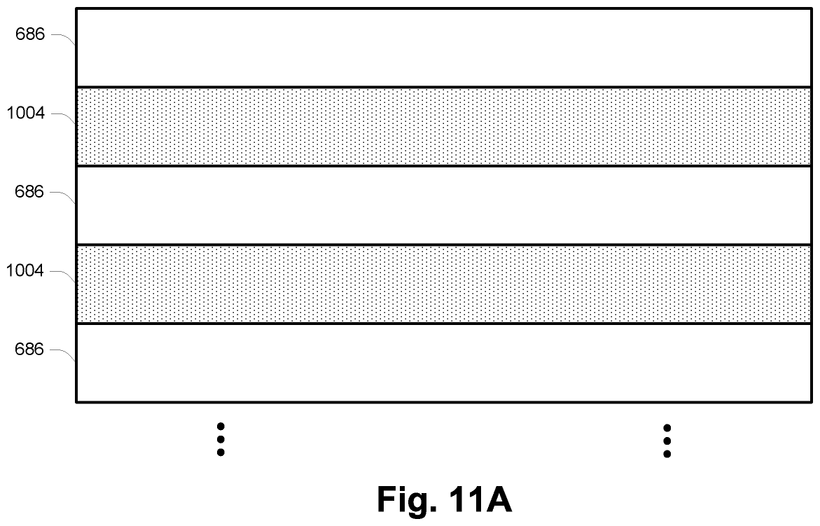

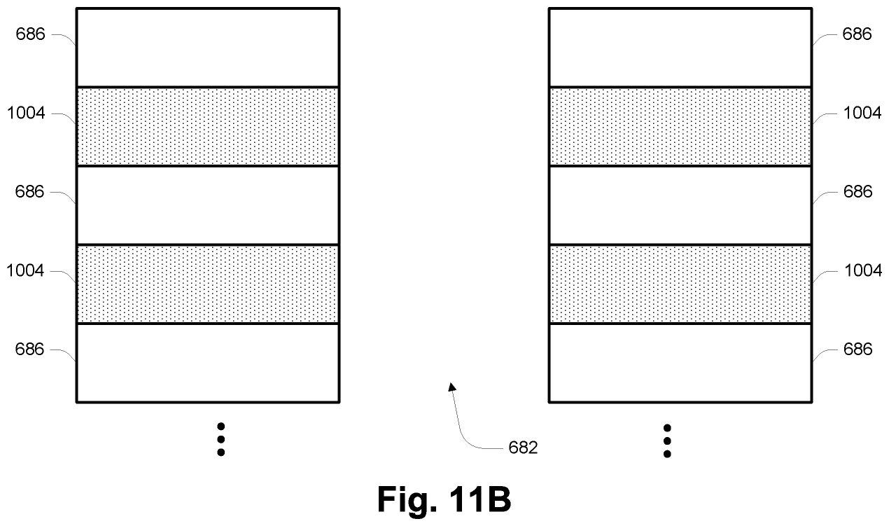

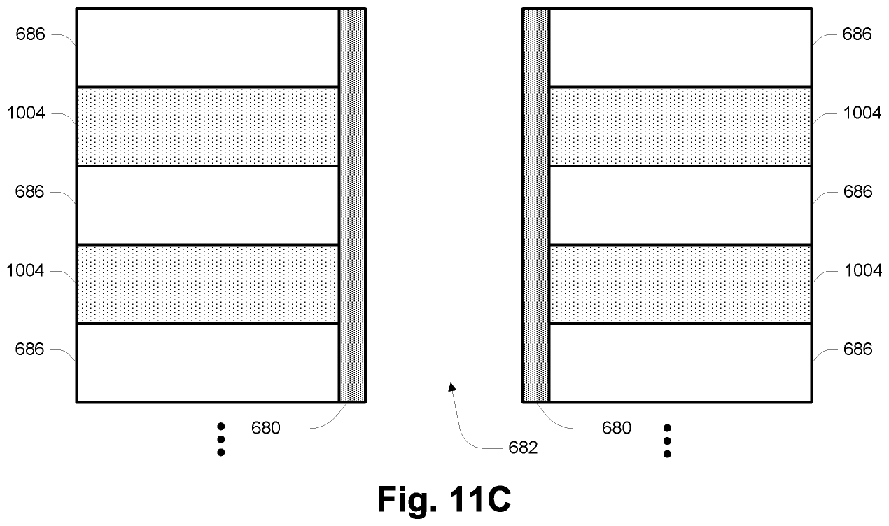

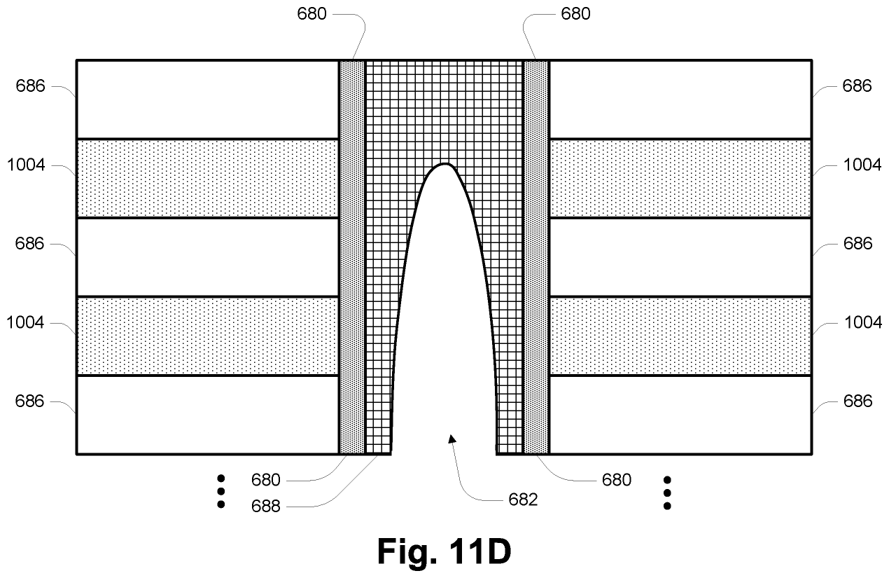

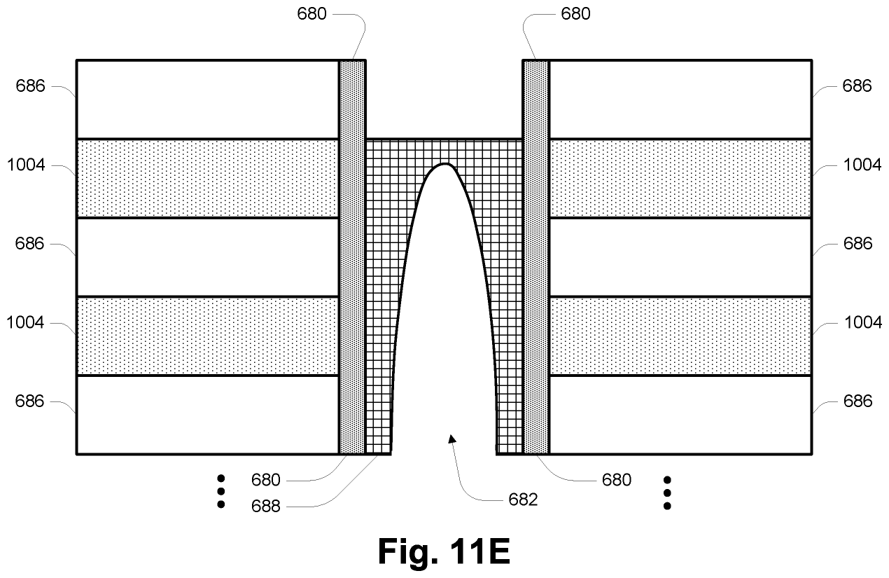

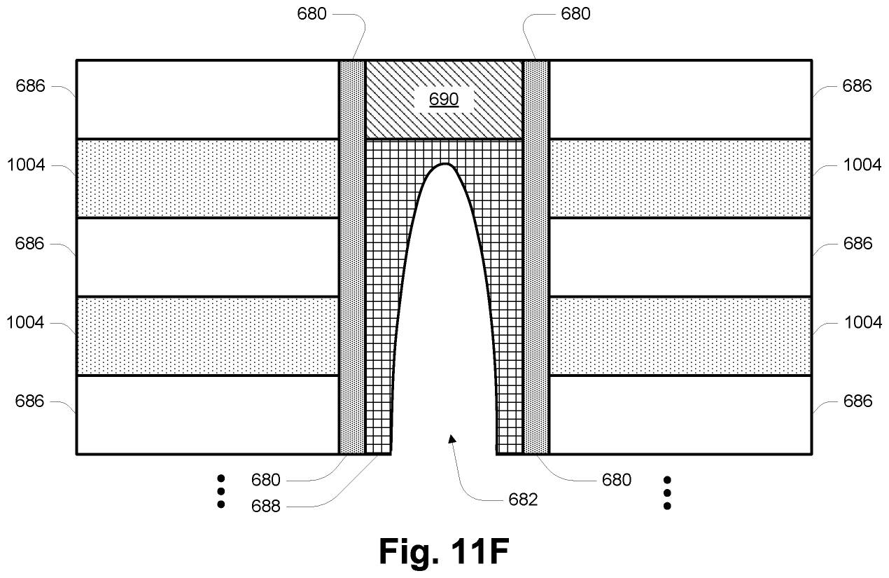

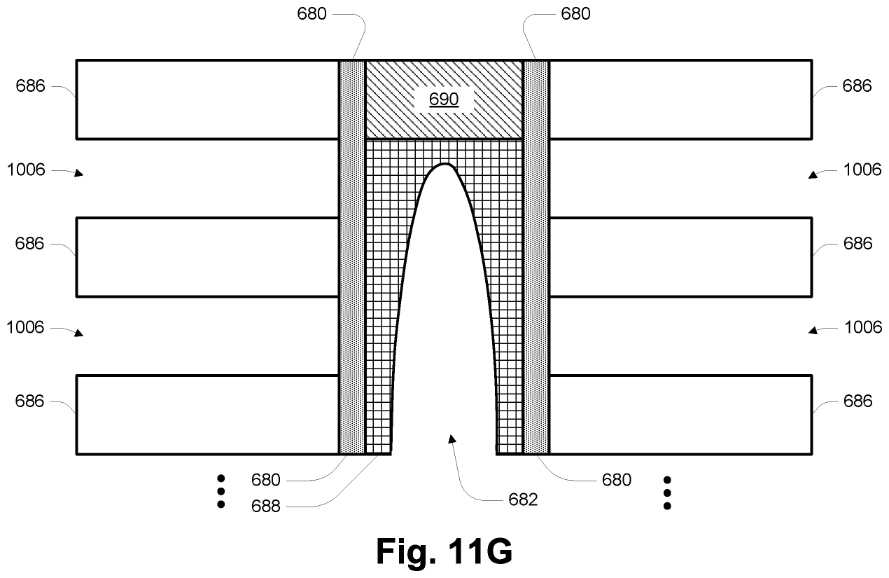

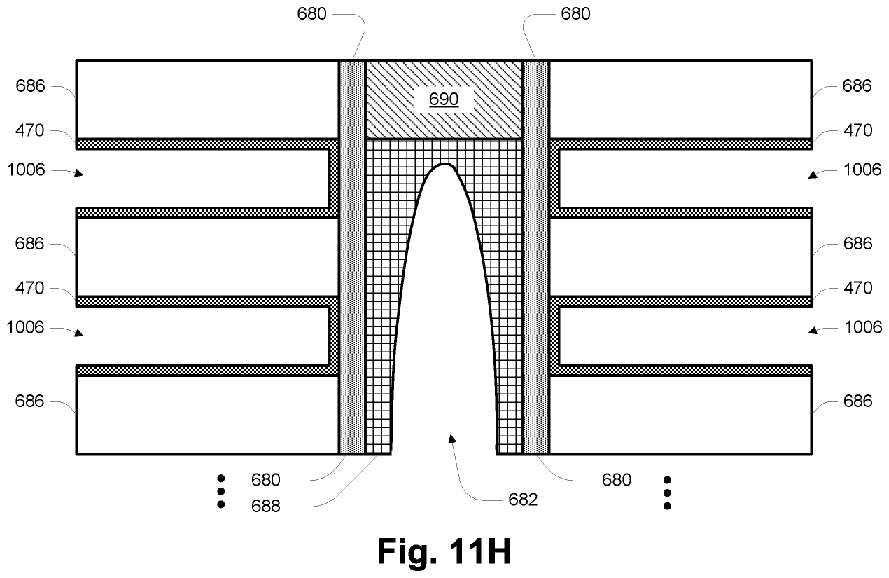

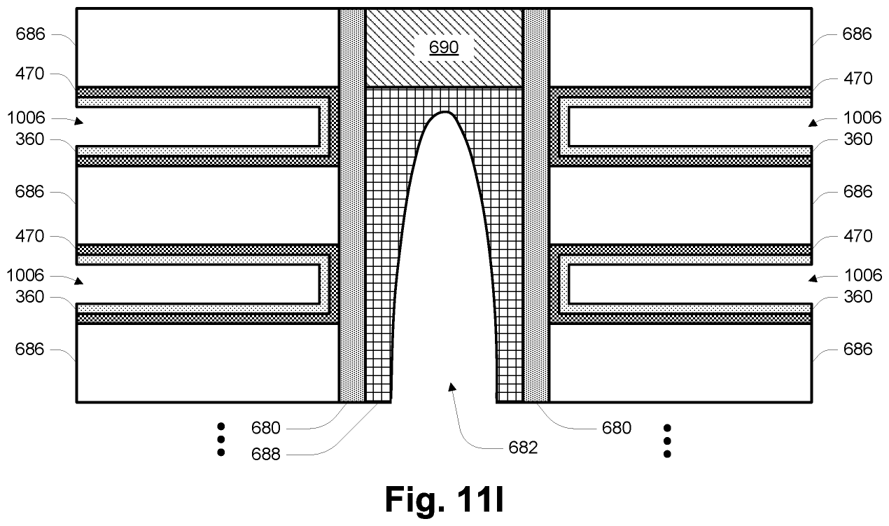

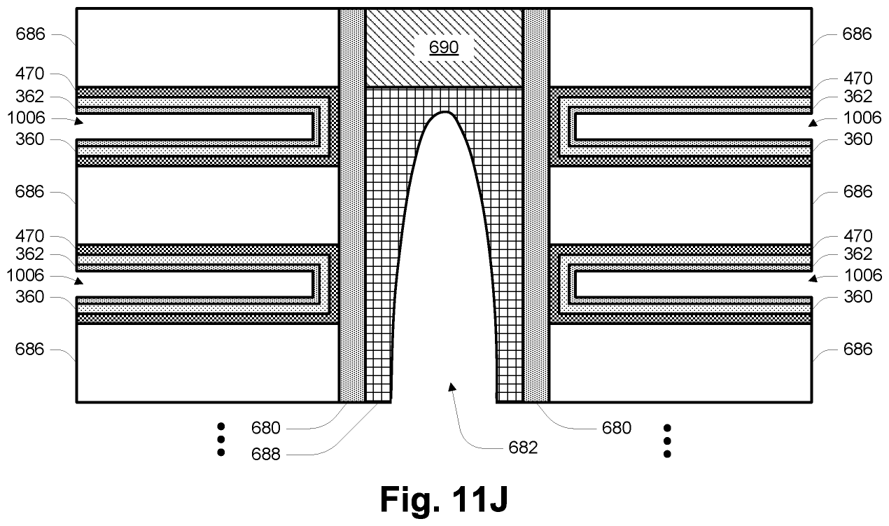

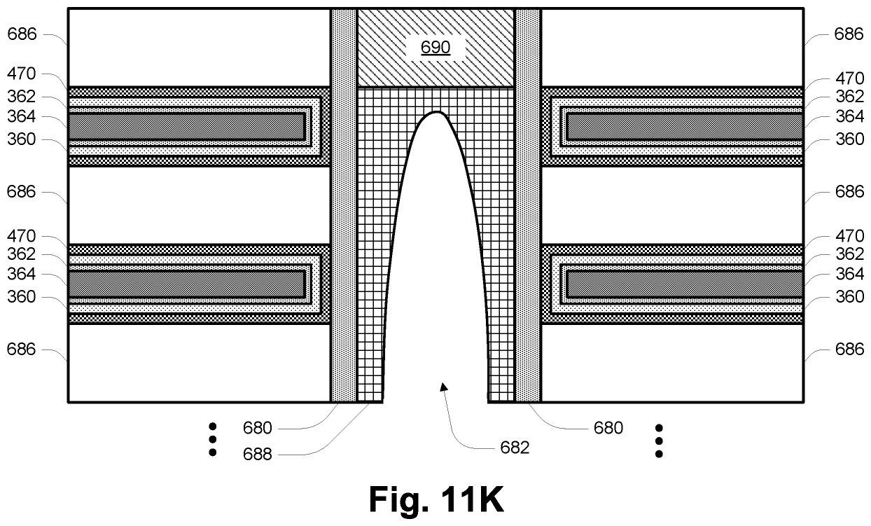

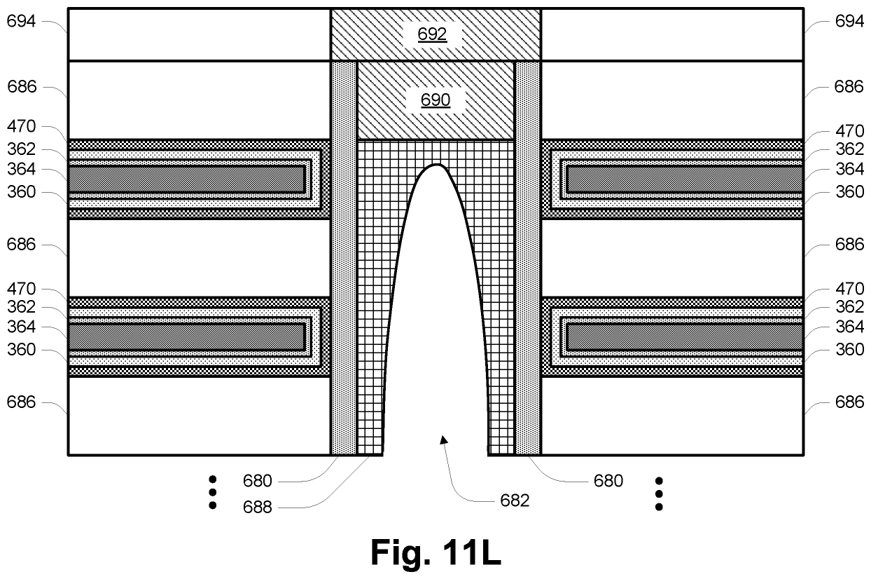

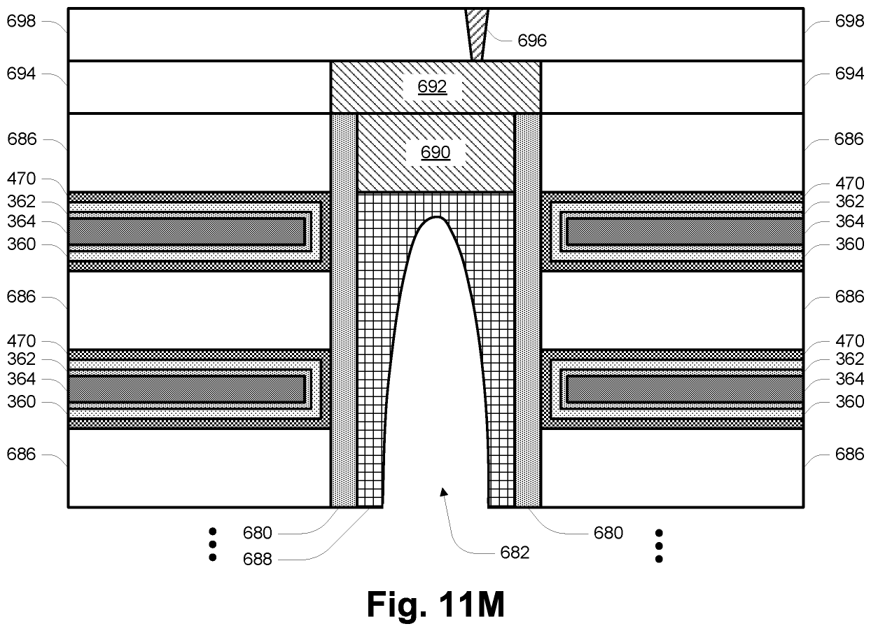

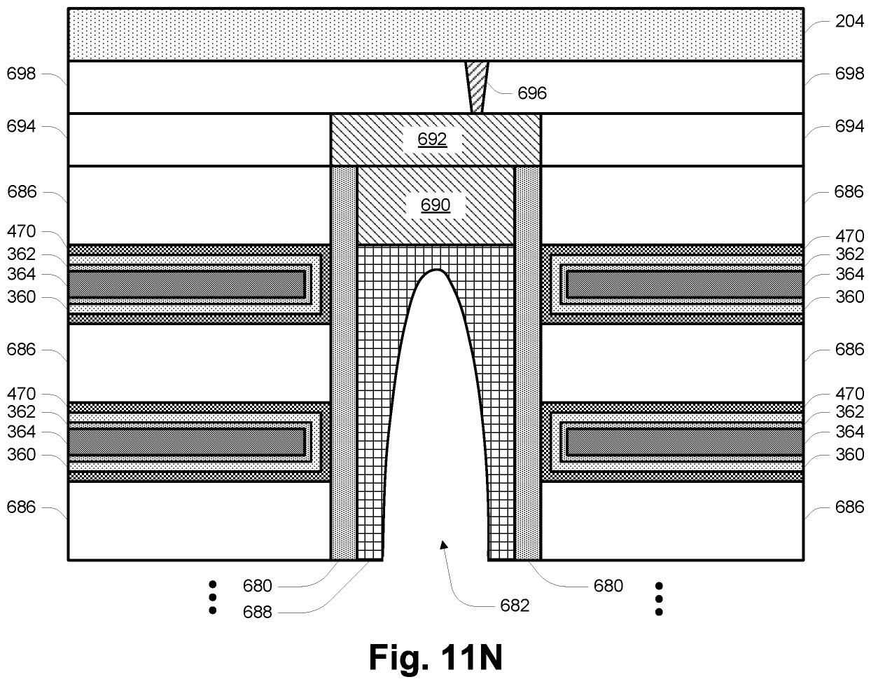

FIGS. 11A-11N depict a memory array structure, which might correspond to a portion of the structure of FIG. 6A, during various stages of fabrication in accordance with an embodiment. FIGS. 11A-11N might be used to describe fabrication of an array of memory cells and associated transistors in accordance with an embodiment, for example. Although transistors depicted to be formed in FIGS. 11A-11N might typically correspond to select gates or GIDL generator gates, their formation as detailed in FIGS. 11A-11N is descriptive of the process to form memory cells.

In FIG. 11A, instances of a dielectric 686 and instances of a sacrificial material 1004 might be formed in an alternating manner. The instances of the sacrificial material 1004 might contain a material that can be subjected to removal without significantly affecting the material(s) of the dielectric 686 or exposed materials of a future channel-material structure 680. As one example, the instances of the sacrificial material 1004 might contain silicon nitride for instances of the dielectric 686 containing silicon dioxide. Additional instances of the dielectric 686 and instances of the sacrificial material 1004 might be formed, depending upon the number of transistors intended to be formed, e.g., memory cells, dummy memory cells, GIDL generator gates, and select gates. While all intended instances of the dielectric 686 and instances of the sacrificial material 1004 might be formed before proceeding to the processing of FIG. 11B, typical processing of such stacked structures might be performed in stages as the aspect ratio of a via formed through the instances of the dielectric 686 and the instances of the sacrificial material 1004 might become too large to form the entire structure reliably as a contiguous entity.

In FIG. 11B, a via or void 682 might be formed through the instances of the dielectric 686 and the instances of the sacrificial material 1004. For example, an anisotropic removal process, e.g., reactive ion etching (RIE), might be used with a contact to the common source 216 (not depicted in FIG. 11B) acting as an etch stop. As such, the void 682 might extend through all instances of the dielectric 686 and through all instances of the sacrificial material 1004.

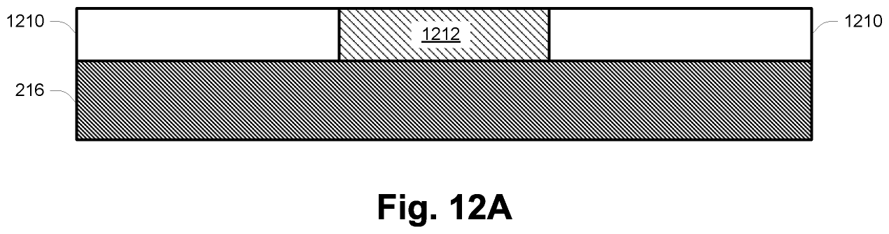

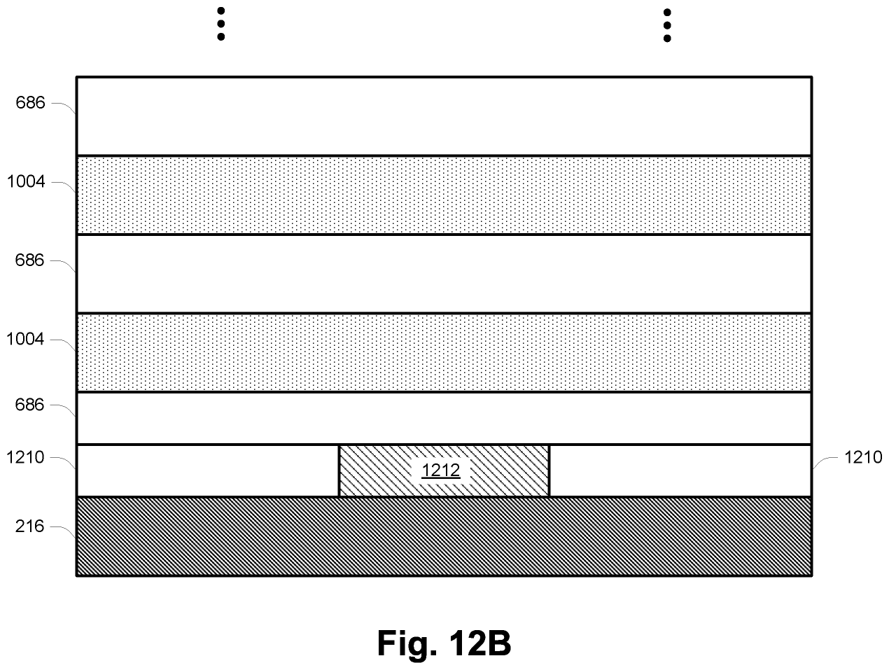

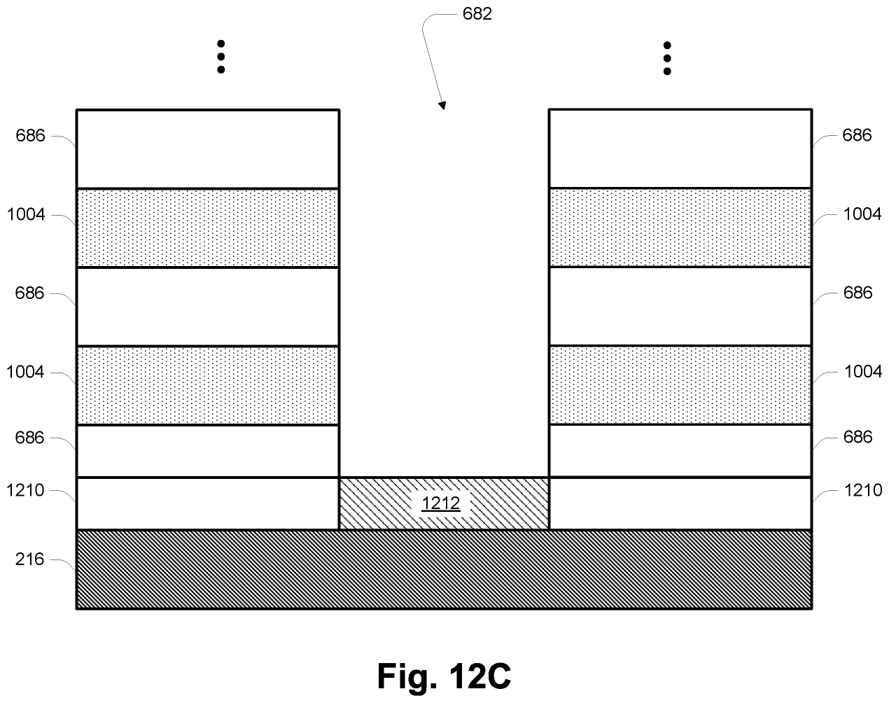

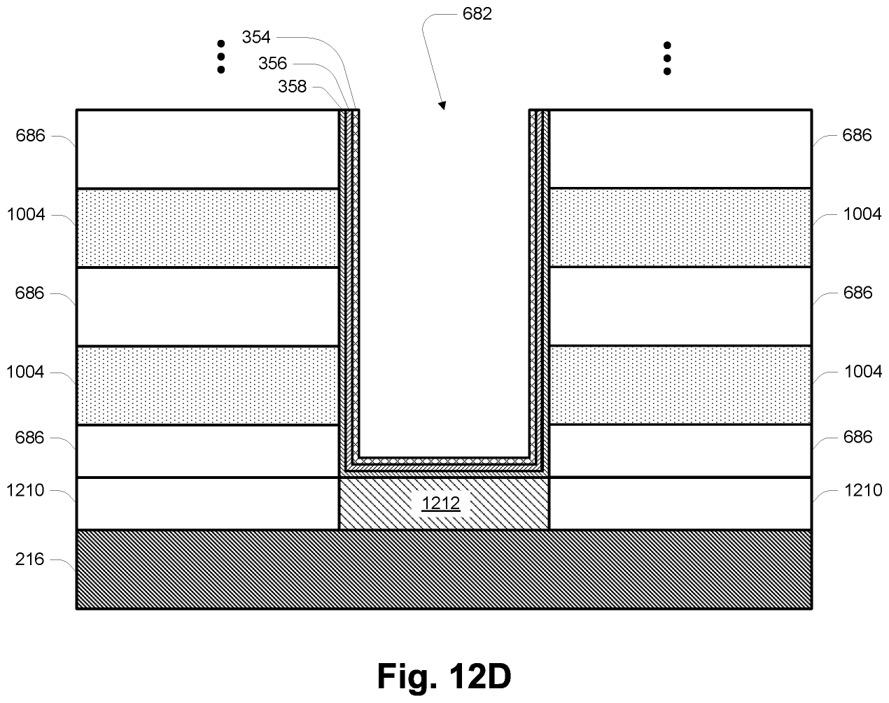

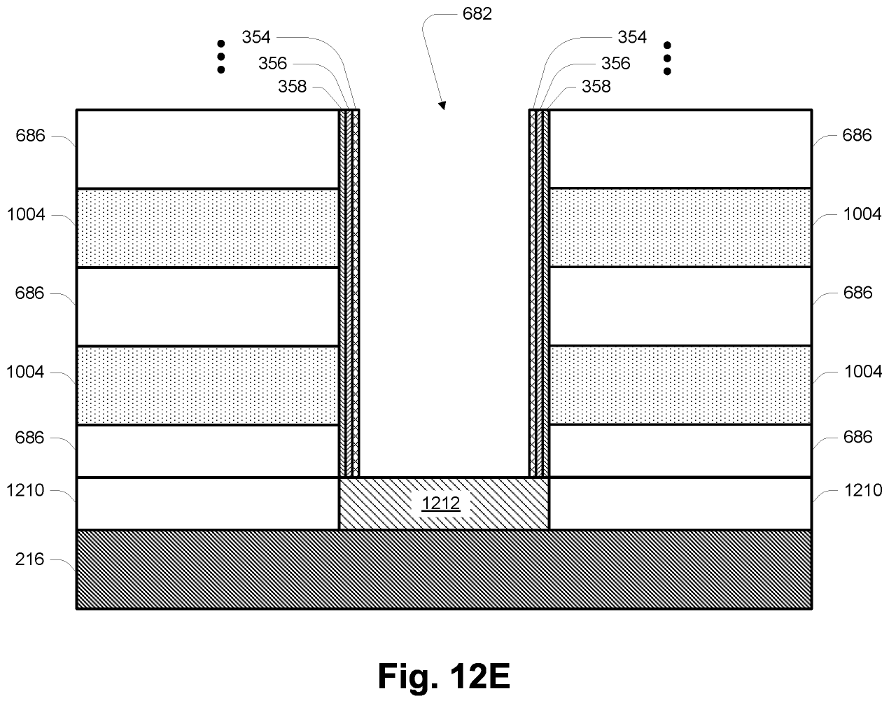

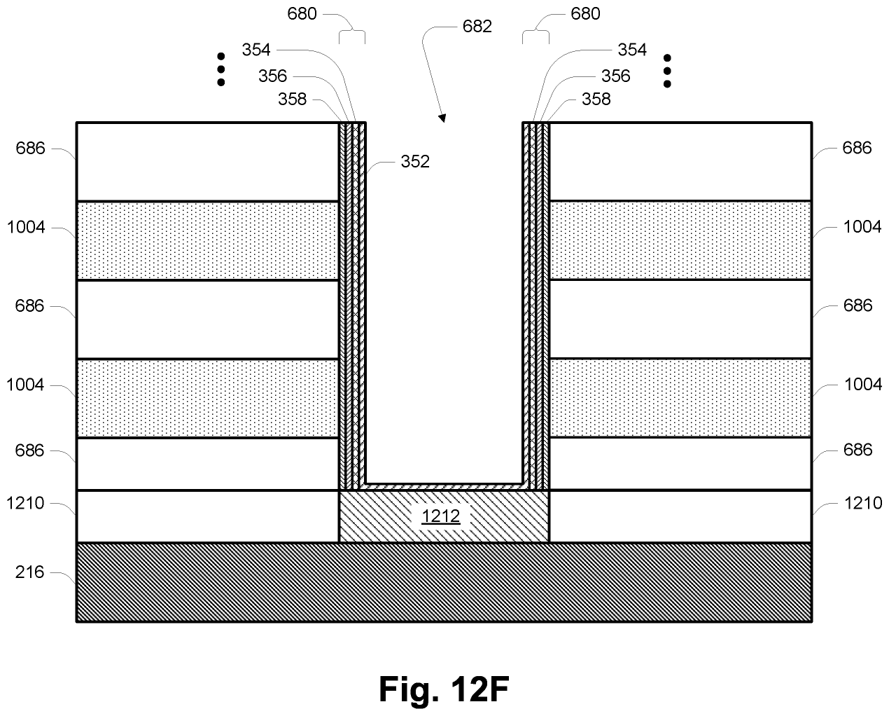

In FIG. 11C, a channel-material structure 680 might be formed to line the sidewalls of the void 682, e.g., formed overlying the sidewalls of the instances of the dielectric 686 and the instances of the sacrificial material 1004. The channel-material structure 680 might have a structure such as depicted in FIG. 6B. Formation of the channel-material structure 680 will be described in more detail with reference to FIGS. 12A-12F.

In FIG. 11D, the dielectric 688 might be formed in the void 682. The dielectric 688 might be deposited overlying the structure of FIG. 11C, and then removed to the level of an upper surface of the upper instance of dielectric 686, such as by chemical-mechanical planarization (CMP). A portion of the void 682 might remain after forming the dielectric 688.

In FIG. 11E, a portion of the dielectric 688 might be removed to recess the upper surface of the dielectric 688. For example, the dielectric 688 might be recessed to expose portions of the channel-material structure 680, and its channel material 352, to a level of the upper instance of sacrificial material 1004. To recess the dielectric 688, the structure of FIG. 11D might be subjected to an isotropic or anisotropic removal process for a particular time expected to recess the dielectric 688 level of the upper instance of sacrificial material 1004. The time expected to result in a desired level of recessing might, for example, be determined experimentally, empirically or through simulation. Isotropic removal processes might involve wet etching processes, e.g., exposing the structure of FIG. 11D to a dilute hydrofluoric acid (HF) solution (e.g., 100:1 H₂O:HF). Isotropic removal processes might alternatively involve dry etching processes, e.g., exposing the structure of FIG. 11D to an oxygen-rich plasma (e.g., 10-100% oxygen by volume). Anisotropic removal processes might involve reactive ion etching. In FIG. 11F, a conductive plug 690 might be formed overlying the dielectric 688 and electrically connected to the channel material 352 of the channel-material structure 680.

In FIG. 11G, the instances of sacrificial material 1004 might be removed to define voids 1006. The removal might include an isotropic removal process, e.g., a plasma etching process. In FIG. 11H, instances of the laminated dielectric 470 might be formed to line the voids 1006. Formation of an instance of the laminated dielectric 470 might include forming an instance of the first dielectric material 472 overlying exposed surfaces of adjacent instances of the dielectric 686 and the exposed surface of an adjacent portion of the channel-material structure 680, and forming an instance of the second dielectric material 474 overlying the instance of the first dielectric material 472. This process could be repeated to produce a desired number of instances of the first dielectric material 472 and the second dielectric material 474 formed in an alternating manner. In FIG. 11I, instances of the high-K dielectric 360 might be formed in the voids 1006 overlying the instances of the laminated dielectric 470. In FIG. 11J, instances of the conductive barrier 362 might be formed in the voids 1006 overlying the instances of the high-K dielectric 360. And in FIG. 11K, instances of the conductor 364 might be formed in the voids 1006 overlying the instances of the conductive barrier 362. The process of FIGS. 11G-11K might be referred to as a replacement gate process, e.g., replacing instances of the sacrificial material with control gates for the transistors.

In FIG. 11L, the contact (e.g., contact plug) 692 might be formed in a dielectric 694, and might be overlying and in physical contact with the channel-material structure 680, and in electrical contact with its channel material 352. The contact 692 might further be overlying and in electrical contact with the conductive plug 690. In FIG. 11M, the contact (e.g., contact via) 696 might be formed in a dielectric 698, and might be overlying and in electrical contact with the contact 692. And in FIG. 11N, the data line 204 might be formed to be overlying and in electrical contact with the conductive via 696.

FIGS. 12A-12F depict a memory array structure during various stages of fabrication in accordance with an embodiment. FIGS. 12A-12F might depict how a memory array structure formed as described with reference to FIGS. 11A-11N could be connected to a common source 216.

If FIG. 12A, a dielectric 1210 might be formed overlying a common source 216, and a contact (e.g., contact plug) 1212 might be formed in the dielectric 1210. The contact 1212 might be overlying and electrically connected to the common source 216. The contact 1212 might contain one or more conductive materials, such as described with reference to the control gates 336. As one example, the contact 1212 might comprise, consist of, or consist essentially of a conductively-doped semiconductor material, such as conductively-doped polysilicon. The dielectric 1210 might contain one or more dielectric materials, such as described with reference to the dielectric 686. As one example, the dielectric 1210 might comprise, consist of, or consist essentially of silicon dioxide.

In FIG. 12B, the instances of the dielectric 686 and the instances of the sacrificial material 1004 might be formed in an alternating manner (e.g., as described with reference to FIG. 11A) overlying the dielectric 1210 and the contact 1212. In FIG. 12C, the via or void 682 might be formed through the instances of the dielectric 686 and the instances of the sacrificial material 1004 as described with reference to FIG. 11B. The void 682 might expose the contact 1212.

In FIG. 12D, the charge-blocking material 358 might be formed overlying the sidewalls of the void 682 (e.g., sidewalls of the instances of the dielectric 686 and the instances of the sacrificial material 1004) and formed overlying the contact 1212. The charge-storage material 356 might be formed overlying the charge-blocking material 358, and the gate dielectric 354 might be formed overlying the charge-storage material 356.

In FIG. 12E, a portion of the charge-blocking material 358, the charge-storage material 356, and the gate dielectric 354 might be removed to expose at least a portion of the contact 1212. For example, a portion of the contact 1212 might be exposed by subjecting the structure of FIG. 12D to an anisotropic removal process, such as reactive ion etching. In FIG. 12F, the channel material 352 might be formed overlying remaining portions of the gate dielectric 354 and overlying the exposed portion of the contact 1212. The channel material 352 might be electrically connected to the contact 1212, and thus electrically connected to the common source 216. The charge-blocking material 358, the charge-storage material 356, the gate dielectric 354, and the channel material 352 overlying the sidewalls of the void 682 might collectively correspond to the channel-material structure 680. Further processing could proceed as described with reference to FIGS. 11D-11N to form all memory cells of a NAND string and their corresponding select gates and other transistors for selective connection to the data line 204 and to the common source 216.

### CONCLUSION

Although specific embodiments have been illustrated and described herein, it will be appreciated by those of ordinary skill in the art that any arrangement that is calculated to achieve the same purpose might be substituted for the specific embodiments shown. Many adaptations of the embodiments will be apparent to those of ordinary skill in the art. Accordingly, this application is intended to cover any adaptations or variations of the embodiments.

1. A memory cell, comprising:
a control gate;
a channel;
a gate dielectric between the channel and the control gate;
a charge-storage node between the gate dielectric and the control gate;
a charge-blocking material between the charge-storage node and the control gate;
a laminated dielectric between the charge-blocking material and the control gate; and
a high-K dielectric between the laminated dielectric and the control gate;
wherein the laminated dielectric comprises an instance of a first dielectric material between the charge-blocking material and the high-K dielectric, and an instance of a second dielectric material between the instance of the first dielectric material and the high-K dielectric; and
wherein the instance of the first dielectric material has a higher oxygen areal density than an oxygen areal density of the instance of the second dielectric material.

2. The memory cell of claim 1, wherein the instance of the first dielectric material has an oxygen areal density that is 20% or higher than the oxygen areal density of the instance of the second dielectric material.

3. The memory cell of claim 1, wherein the instance of the second dielectric material is a first instance of the second dielectric material, and wherein the laminated dielectric further comprises a second instance of the second dielectric material between the instance of the first dielectric material and the charge-blocking material.

4. The memory cell of claim 1, wherein the instance of the first dielectric material is a first instance of the first dielectric material of a plurality of instances of the first dielectric material, wherein the instance of the second dielectric material is a first instance of the second dielectric material of a plurality of instances of the second dielectric material, and wherein the plurality of instances of the first dielectric material and the plurality of instances of the second dielectric material are arranged in an alternating fashion between the charge-blocking material and the high-K dielectric.

5. The memory cell of claim 4, wherein each instance of the first dielectric material of the plurality of instances of the first dielectric material has a higher oxygen areal density than an oxygen areal density of each instance of the second dielectric material of the plurality of instances of the second dielectric material.

6. The memory cell of claim 5, wherein each instance of the first dielectric material of the plurality of instances of the first dielectric material comprises a same dielectric material as each remaining instance of the first dielectric material of the plurality of instances of the first dielectric material.

7. The memory cell of claim 5, wherein each instance of the second dielectric material of the plurality of instances of the second dielectric material comprises a same dielectric material as each remaining instance of the second dielectric material of the plurality of instances of the second dielectric material.

8. A memory, comprising:
a plurality of data lines;
a common source;
an array of memory cells comprising a plurality of strings of series-connected memory cells each selectively connected to a respective data line of the plurality of data lines and each selectively connected to the common source; and
a controller for access of the array of memory cells;
wherein at least one memory cell of a particular string of series-connected memory cells of the plurality of strings of series-connected memory cells comprises:
a control gate;
a channel;
a gate dielectric between the channel and the control gate;
a charge-storage node between the gate dielectric and the control gate;
a charge-blocking material between the charge-storage node and the control gate;
a laminated dielectric between the charge-blocking material and the control gate; and
a high-K dielectric between the laminated dielectric and the control gate;
wherein the laminated dielectric comprises an instance of a first dielectric material between the charge-blocking material and the high-K dielectric, and an instance of a second dielectric material between the instance of the first dielectric material and the high-K dielectric; and
wherein the instance of the first dielectric material has a higher oxygen areal density than an oxygen areal density of the instance of the second dielectric material.

9. The memory array structure of claim 8, wherein the instance of the first dielectric material is a first instance of the first dielectric material of a plurality of instances of the first dielectric material, wherein the instance of the second dielectric material is a first instance of the second dielectric material of a plurality of instances of the second dielectric material, and wherein the plurality of instances of the first dielectric material and the plurality of instances of the second dielectric material are arranged in an alternating fashion between the charge-blocking material and the high-K dielectric.

10. The memory array structure of claim 9, wherein each instance of the first dielectric material of the plurality of instances of the first dielectric material has a higher oxygen areal density than an oxygen areal density of each instance of the second dielectric material of the plurality of instances of the second dielectric material.

11. The memory array structure of claim 10, wherein each instance of the first dielectric material of the plurality of instances of the first dielectric material comprises a same dielectric material as each remaining instance of the first dielectric material of the plurality of instances of the first dielectric material.

12. The memory array structure of claim 10, wherein each instance of the second dielectric material of the plurality of instances of the second dielectric material comprises a same dielectric material as each remaining instance of the second dielectric material of the plurality of instances of the second dielectric material.

13. The memory array structure of claim 8, wherein an interface between the charge-blocking material and the instance of the first dielectric material is more abrupt than an interface between the instance of the first dielectric material and the instance of the second dielectric material.

14. A memory array structure, comprising:
a data line;
a common source; and
a channel-material structure between the data line and the common source;
a control gate surrounding the channel-material structure;
a laminated dielectric between the channel-material structure and the control gate; and
a high-K dielectric between the laminated dielectric and the control gate;
wherein the channel-material structure comprises:
a channel material electrically connected to the common source and electrically connected to the data line;
a gate dielectric between the channel material and the control gate;
a charge-storage node between the gate dielectric and the control gate; and
a charge-blocking material between the charge-storage node and the control gate;
wherein the laminated dielectric comprises an instance of a first dielectric material between the channel-material structure and the high-K dielectric, and an instance of a second dielectric material between the instance of the first dielectric material and the high-K dielectric; and
wherein the instance of the first dielectric material has a higher oxygen areal density than an oxygen areal density of the instance of the second dielectric material.

15. The memory array structure of claim 14, wherein the laminated dielectric comprising the instance of the first dielectric material and the instance of the second dielectric material is a first laminated dielectric comprising a first instance of the first dielectric material and a first instance of the second dielectric material, wherein the channel-material structure further comprises a second laminated dielectric between the first laminated dielectric and the charge-blocking material, and wherein the second laminated dielectric comprises a second instance of the first dielectric material between the charge-blocking material and the first laminated dielectric, and a second instance of the second dielectric material between second instance of the first dielectric material and the first laminated dielectric.

16. The memory array structure of claim 14, wherein the instance of the first dielectric material is a first instance of the first dielectric material of a plurality of instances of the first dielectric material, wherein the instance of the second dielectric material is a first instance of the second dielectric material of a plurality of instances of the second dielectric material, and wherein the plurality of instances of the first dielectric material and the plurality of instances of the second dielectric material are arranged in an alternating fashion between the charge-blocking material and the high-K dielectric.

17. The memory array structure of claim 16, wherein the first instance of the first dielectric material is immediately adjacent the channel-material structure, and wherein a last instance of the second dielectric material is immediately adjacent the high-K dielectric.

18. The memory array structure of claim 16, wherein each instance of the first dielectric material of the plurality of instances of the first dielectric material has a higher oxygen areal density than an oxygen areal density of each instance of the second dielectric material of the plurality of instances of the second dielectric material.

19. (canceled)

20. The memory array structure of claim 16, wherein each instance of the first dielectric material of the plurality of instances of the first dielectric material has an oxygen areal density that is 20% or higher than the oxygen areal density of each immediately adjacent instance of the second dielectric material of the plurality of instances of the second dielectric material.

21. The memory array structure of claim 16, wherein each instance of the first dielectric material of the plurality of instances of the first dielectric material comprises a respective dielectric material selected from a group consisting of scandium(III) oxide (Sc₂O₃), magnesium oxide (MgO), zirconium dioxide (ZrO₂), hafnium dioxide (HfO₂), tantalum pentoxide (Ta₂O₅), titanium dioxide (TiO₂), and aluminum(III) oxide (Al₂O₃), and wherein each instance of the second dielectric material of the plurality of instances of the second dielectric material comprises a respective dielectric material selected from a group consisting of silicon dioxide (SiO₂) and germanium dioxide (GeO₂).

22-25. (canceled)
